(19) United States
(12) Patent Application Publication
(10) Pub. No.: US 2024/0265476 A1
(43) Pub. Date: Aug. 8, 2024

(54) COMMUNICATION TERMINAL, TRACKING SYSTEM, DISPLAYING METHOD, AND NON-TRANSITORY RECORDING MEDIUM

(71) Applicant: Ricoh Company, Ltd., Tokyo (JP)

(72) Inventors: Yuzo AOSHIMA, Tokyo (JP); Ryusuke MAYUZUMI, Kanagawa (JP)

(73) Assignee: Ricoh Company, Ltd., Tokyo (JP)

(21) Appl. No.: 18/607,336

(22) Filed: Mar. 15, 2024

Related U.S. Application Data
(62) Division of application No. 17/205,038, filed on Mar. 18, 2021.

(30) Foreign Application Priority Data
Mar. 19, 2020 (JP) 2020-049304
Mar. 31, 2020 (JP) 2020-062848
Feb. 5, 2021 (JP) 2021-017297

(51) Int. Cl. G06Q 50/06; G01R 22/06; G06Q 30/018; G06Q 30/0283

(52) U.S. Cl. CPC G06Q 50/06; G01R 22/063; G06Q 30/018; G06Q 30/0283; G06Q 2220/00

(57) ABSTRACT

A communication terminal includes circuitry to receive one or more user inputs specifying conditions related to future energy consumption. The circuitry further displays, on a display, a first energy consumption recommendation that is determined based on the specified conditions and a record of past energy consumption and receives a user operation to confirm or change the first energy consumption recommendation. When the user operation is a change of the first energy consumption recommendation, the circuitry further displays a second energy consumption recommendation according to the change and receives another user operation to confirm the second energy consumption recommendation. The circuitry outputs confirmation of the first energy consumption recommendation or the second energy consumption recommendation as details of the future energy consumption.

### CROSS-REFERENCE TO RELATED APPLICATIONS

This patent application is a divisional of U.S. application Ser. No. 17/205,038, filed Mar. 18, 2021, which is based on and claims priority pursuant to 35 U.S.C. § 119(a) to Japanese Patent Application Nos. 2020-049304, filed on Mar. 19, 2020, 2020-062848, filed on Mar. 31, 2020, and 2021-017297, filed on Feb. 5, 2021, in the Japan Patent Office, the entire disclosures of each are hereby incorporated by reference.

### BACKGROUND

### Technical Field

Embodiments of the present disclosure relate to a communication terminal, a tracking system, a displaying method, and a non-transitory recording medium storing instructions.

### Related Art

In recent years, electricity produced from renewable energy source has been attracting attention. In this disclosure, the electricity produced from renewable energy source is defined as electricity produced from a subset of renewable resources such as solar (solar light or solar heat), wind power, biomass, geothermal power, hydropower, and heat in the atmosphere. Compared to the case where the fossil fuel such as oil, coal, and liquefied natural gas is used to produce electricity, production of electricity using renewable energy source emits almost no carbon dioxide (CO2), which is a cause for global warming. That is, renewable energy is an energy resource that is environmentally friendly, from among various energy resources used for producing electricity today. By operating such as factories using the above-described power based on renewable energy source, which is environmentally friendly, companies can increase brand credibility.

There is a known method that allows an electricity consumer to purchase electricity by using a blockchain (blockchain network). In such a method, users who are to use an electricity such as electricity may desire to flexibly select energy resources that are used to produce the electricity, because the electricity produced by solar power is difficult to be obtained during a period in which days are short, and the electricity produced by oil is stable in supply but not environmentally friendly, for example.

### SUMMARY

An exemplary embodiment of the present disclosure includes a communication terminal including circuitry to receive one or more user inputs specifying conditions related to future energy consumption. The circuitry further displays, on a display, a first energy consumption recommendation that is determined based on the specified conditions and a record of past energy consumption and receives a user operation to confirm or change the first energy consumption recommendation. When the user operation is a change of the first energy consumption recommendation, the circuitry further displays a second energy consumption recommendation according to the change and receives another user operation to confirm the second energy consumption recommendation. The circuitry outputs confirmation of the first energy consumption recommendation or the second energy consumption recommendation as details of the future energy consumption.

### BRIEF DESCRIPTION OF THE DRAWINGS

A more complete appreciation of the disclosure and many of the attendant advantages and features thereof can be readily obtained and understood from the following detailed description with reference to the accompanying drawings, wherein:

FIG. 1 is a schematic view illustrating an example of tracking system according to an exemplary embodiment;

FIG. 2 is a schematic diagram illustrating a hardware configuration of a smartphone according to the exemplary embodiment;

FIG. 3 is a schematic diagram illustrating a hardware configuration of a smart meter according to the exemplary embodiment;

FIG. 4 is a schematic diagram illustrating a hardware configuration of an intermediary server according to the exemplary embodiment;

FIG. 5 is a schematic block diagram illustrating functional configurations of the smartphone and the smart meter in the tracking system of FIG. 1, according to the exemplary embodiment;

FIG. 6 is a schematic block diagram illustrating a functional configuration of the intermediary server and the node in the tracking system of FIG. 1, according to the exemplary embodiment;

FIG. 7A is a conceptual diagram illustrating an example of user management table; FIG. 7B is a conceptual diagram illustrating an example of supplier management table;

FIG. 8A is a conceptual diagram illustrating an example of usage plan management table;

FIG. 8B is a conceptual diagram illustrating an example of usage history management table;

FIG. 9 is a sequence diagram illustrating example processing of registering intermediary agents;

FIG. 10A is an illustration of an example intermediary agent registration screen;

FIG. 10B is an illustration of an example intermediary agent registration completion screen;

FIG. 11 is a sequence diagram illustrating processing of registering usage conditions for an asset according to the exemplary embodiment;

FIG. 12A is an illustration of an example usage conditions registration screen before information is entered or selected, according to the exemplary embodiment;

FIG. 12B is an illustration of an example usage conditions registration screen after information is entered or selected, according to the exemplary embodiment;

FIG. 13 is a sequence diagram illustrating processing of registering usage conditions for an asset according to the exemplary embodiment;

FIG. 14A is an illustration of an example of usage plan setting screen displaying a recommendation originally provided by giving priority to achieving a renewable energy usage ratio, according to the exemplary embodiment;

FIG. 14B is an illustration of an example of usage plan setting screen displaying another recommendation provided by giving priority to achieving the renewable energy usage ratio, and provided after the previous recommendation is modified, according to the exemplary embodiment;

FIG. 15 is an illustration of another example of usage plan setting screen displaying a recommendation that is determined by giving priority to the lowest cost, according to the exemplary embodiment;

FIG. 16 is an illustration of still another example of usage plan setting screen displaying a recommendation that is determined by giving priority to CO2 emissions reduction, according to the exemplary embodiment;

FIG. 17 is a sequence diagram illustrating processing of setting the intermediary agent as an owner of the asset provided by the supplier, according to the exemplary embodiment;

FIG. 18 is a conceptual diagram illustrating transaction information and asset information according to the embodiment;

FIG. 19 is a sequence diagram illustrating processing of setting the user as an owner of the asset, according to the embodiment.

FIG. 20 is a conceptual diagram illustrating transaction information and asset information, when estimated electricity consumption is equal to or greater than electricity consumption that is available, according to the exemplary embodiment; and

FIG. 21 is a sequence diagram illustrating processing of facilitating a production method certificate of an asset, according to the exemplary embodiment.

The accompanying drawings are intended to depict embodiments of the present invention and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

The terminology used herein is for the purpose of describing particular embodiments only and is not intended to be limiting of the present invention. As used herein, the singular forms “a,” “an,” and “the” are intended to include the plural forms as well, unless the context clearly indicates otherwise.

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Embodiments of the present disclosure are described in detail below, with reference to the drawings.

### Overview of System Configuration:

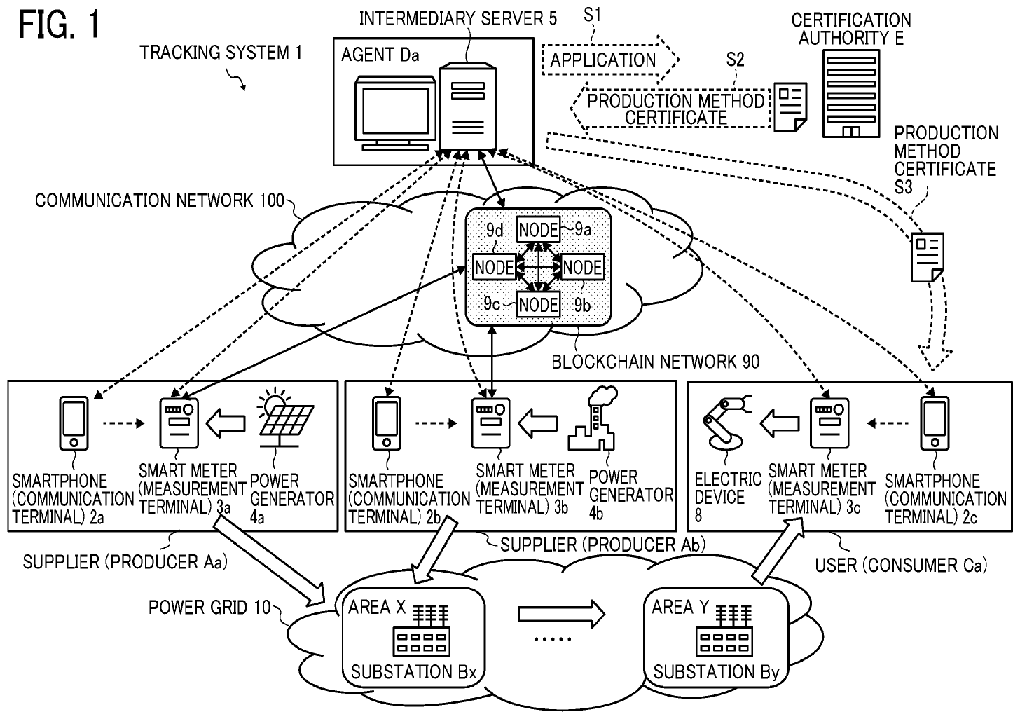

First, overview of a configuration of a tracking system 1 is described according to one or more exemplary embodiments. In the description of one or more embodiments given below, the tracking system 1 maybe referred to as a system for managing energy consumption. FIG. 1 is a schematic view illustrating an example of tracking system according to the exemplary embodiment. Here, the case in which electricity is used as an example of an asset is described. In this description of one or more embodiments, the asset is an item that has value. The ownership of the asset and the production method of the asset are managed using asset information described later.

### Explanation on Each Entity in Tracking System:

As illustrated in FIG. 1, the tracking system 1 is used by a producer Aa of electricity, a producer Ab of electricity, a consumer Ca of electricity, an intermediary agent Da, and a certification authority E.

Producer Aa, an example of a supplier, is an entity that produces electricity from solar light, as one example of an entity that produces electricity from renewable energy source, or renewable energy resource. In this description of one or more embodiments, electricity produced from renewable energy source, or renewable energy resource is referred to as green power.

Producer Ab, an example of a supplier, is an entity that produces electricity from oil as an example of fossil fuel. The supplier may be a union that purchases items from each producer and resells the items.

The consumer Ca, an example of a user, is an entity that consumes electricity supplied from the producer Aa or Ab. In case the asset is not consumed like electricity, such as in the case of a real estate property, the user may be an owner who currently owns the asset.

The intermediary agent Da is an entity that intermediates transfer of ownership of electricity between different entities.

The certification authority E is a public institution such as a national or local public entity that certifies a certain type of electricity production method. Electricity production methods can be determined based on, for example, a type of energy resource used to produce electricity. Assuming that the electricity production method is defined by a type of energy resource, examples of electricity production method include a production method using solar (such as solar light or solar heat), a production method using wind (such as wind power), a production method using biomass, a production method using geothermal power, a production method using hydroelectric resources, a production method using heat in the atmosphere, and a production method using nuclear power. Of those various types of electricity production methods, the electricity production methods using renewable energy resources, or renewable energy sources, such as solar light, solar heat, wind power, biomass, geothermal power, hydropower, and heat in the atmosphere are grouped into a production method using renewable energy source. The electricity production methods using petroleum (oil), coal, and liquefied natural gas are grouped into a production method using conventional energy such as fossil fuel. Compared to the production method using conventional energy, the production method using renewable energy source emits almost no carbon dioxide (CO2), which is a cause for global warming. That is, renewable energy source is an energy resource that is environmentally friendly. In this description of one or more embodiments, as examples of renewable energy resource, solar light, or solar heat (solar power), wind power, biomass, geothermal power, hydropower, and heat in the atmosphere are referred, for descriptive purposes. Further, as examples of conventional energy resource, fossil fuel, such as oil, coal, and liquefied natural gas are referred, for descriptive purposes.

The intermediary agent Da, as an intermediator, sends an application form to the certification authority E by mail or the like on behalf of the customer Ca, receives a production method certificate of the customer Ca from the certification authority E, and sends the production method certificate to the consumer Ca by mail or the like. The production method certificate, for example, describes a usage ratio of renewable energy source, which is a ratio that the customer Ca uses electricity produced from renewable energy source, among electricity consumed by the customer Ca. With the production method certificate, the consumer Ca can apply for public subsidy, based on the renewable energy usage ratio (or CO2 reduction rate) of the consumer Ca, or total usage of renewable energy of the consumer Ca.

The number of producers may be one or three or more. There may be multiple consumers or intermediary agents.

### Power Transmission and Distribution Network:

The substation Bx is a substation nearest to the producers Aa and Ab. The substation By is a substation nearest to the consumer Ca. The power distribution network 10, which may be referred to as the power grid 10, includes substations Bx and By, and transmission lines, and distribution lines, etc. The electricity supplied from the producers Aa and Ab is distributed to the consumer Ca via the power grid 10.

### Data Communication Network:

The producer Aa is equipped with a smartphone 2a, a smart meter 3a, and a power generator 4a. The producer Ab is equipped with a smartphone 2b, a smart meter 3b, and a power generator 4b. The consumer Ca is equipped with a smartphone 2c, a smart meter 3c, and an electric device 8. The intermediary agent Da manages an intermediary server 5. The intermediary agent Da may be an organization such as a corporation or an individual (for example, a president, an executive officer, or an employee such as an information technology (IT) system administrator). The number of smartphones may be two or four or more, for example, depending on the number of producers and consumers. Hereinafter, the smartphones 2a, 2b, and 2c may be collectively referred to as the smartphone 2. Further, the number of smart meters 3a, 3b, and 3c may be two or four or more, for example, depending on the number of producers and consumers. Hereinafter, the smart meters 3a, 3b, and 3c may be collectively referred to as the smart meter 3. The number of power generators 4a and 4b may be one or three or more, for example, depending on the number of producers. Hereinafter, the power generators 4a and 4b may be collectively referred to as the power generator 4.

The number of intermediary servers 5 maybe two or more, for example, depending on the number of intermediary agents. Further, the intermediary server 5 maybe implemented by a single computer or a plurality of computers. The number of electric devices 8 maybe two or more, for example, depending on the number of consumers. Because further registering details for future electricity consumption (future energy consumption), or details for electricity transaction to be executed, the intermediary server 5 maybe also referred to as a “registration server”. Alternatively, in addition to the intermediary server 5, another server may be used as a registration server that registers details for a future electricity consumption.

As illustrated in FIG. 1, the tracking system 1 that resides on a data communication network includes the plurality of smartphones 2a, 2b, and 2c, the plurality of smart meters 3a, 3b, and 3c, the plurality of power generators 4a and 4b, the intermediary server 5, and a plurality of nodes 9a, 9b, 9c, and 9d each implemented by such as a computer. In this embodiment, the nodes 9a, 9b, 9c, and 9d form a blockchain network 90. The blockchain network 90 is formed on the communication network 100 such as the Internet. The communication network 100 includes the Internet, a mobile communication network, a local area network (LAN), and the like. The communication network 100 may include not only a wired communication network but also a wireless communication network such as a mobile communication system (4G, 5G, 6G, etc.) and Worldwide Interoperability for Microwave Access (WiMAX). Although there are actually a large number of nodes exist, only four nodes 9a, 9b, 9c, and 9d are illustrated in the figure for simplicity. In this exemplary embodiment, the nodes 9a, 9b, 9c, and 9d are managed by different organizations such as different companies. The intermediary agent Da may be any one of these different organizations. For example, the intermediary server 5 and any one of the nodes 9a, 9b, 9c, and 9d may be managed by the same organization. Hereinafter, the nodes 9a, 9b, 9c, and 9d may be collectively referred to as the node 9.

Next, the terminals and devices of the producers Aa and Ab and the consumer Ca are described.

### Terminals and Devices of Producer Aa:

The smartphone 2a communicates data with the smart meter 3a by short-range wireless technology such as Near Field Communication (NFC) or Bluetooth. Further, the smartphone 2a communicates data with the intermediary server 5 via the communication network 100.

The smart meter 3a communicates data with the intermediary server 5 via the communication network 100. Further, the smart meter 3a measures an amount of electricity produced by the power generator 4a every predetermined time period (for example, every 30 minutes). The smart meter 3a performs processing such as requesting the node 9 of the blockchain network 90 to generate asset information indicating the amount of asset that can be provided such as electric power and the ownership of such asset.

The power generator 4a is a device that generates electricity from solar light.

### Terminals and Devices of Producer Ab:

The smartphone 2b communicates data with the smart meter 3b by short-range wireless technology such as NFC or Bluetooth. Further, the smartphone 2b communicates data with the intermediary server 5 via the communication network 100.

The smart meter 3b communicates data with the intermediary server 5 via the communication network 100. Further, the smart meter 3b measures an amount of electricity produced by the power generator 4b every predetermined time period (for example, every 30 minutes). The smart meter 3a performs processing such as requesting the node 9 of the blockchain network 90 to generate asset information indicating the amount of asset that can be provided such as electric power and the ownership of such asset.

The power generator 4b is a device that generates electricity from oil.

### Terminals and Devices of Consumer Ca:

The smartphone 2c communicates data with the smart meter 3c by short-range wireless technology such as NFC or Bluetooth. Further, the smartphone 2c communicates data with the intermediary server 5 via the communication network 100.

The smart meter 3c communicates data with the intermediary server 5 via the communication network 100. Further, the smart meter 3c measures an amount of electricity consumed by the electric device 8 every predetermined time period (for example, every 30 minutes). The smart meter 3c performs processing such as transmitting usage information indicating the amount of electricity consumed, and a duration of time when electricity is consumed, etc., to the intermediary server 5 via the communication network 100. In the exemplary embodiment, since the intermediary server 5 accesses the blockchain network 90 on behalf of the smart meter 3c, the smart meter 3c does not need to directly access the blockchain network 90. To access the blockchain network 90 on behalf of the smart meter 3c, the intermediary server 5 previously stores, in the storage unit 5000, a certificate of the consumer Ca that is required to access the blockchain network 90 from the smart meter 3c.

The electric device 8 is any device that is operated with electricity supplied by the consumers Aa and/or Ab.

### Intermediary Server of Intermediary Agent Da:

The intermediary server 5 intermediates transaction of asset between a supplier and a user. Specifically, the intermediary agent intermediates ownership of asset between the supplier and the user. In this description of one or more embodiments, the example case in which the asset, which is an item, is electricity is described. The intermediary server 5 communicates data with each smartphone 2 and each smart meter 3 via the communication network 100. Further, the intermediary server 5 accesses the blockchain network 90 to enable tracking of transaction of asset (electricity transaction, energy transaction). In example operation, the intermediary server 5 accesses the node 9 of the blockchain network 90 to communicate data with the node 9. In the example case of asset being electricity, the tracking system 1 tracks electricity from the supplier to the user.

Smartphones 2a and 2b are examples of communication terminals of the providers. The smartphone 2c is an example of a communication terminal of the user. Examples of communication terminal also include smart watches, PCs, and smart glasses. The smart meter 3 is an example of a measurement terminal.

### Hardware Configuration:

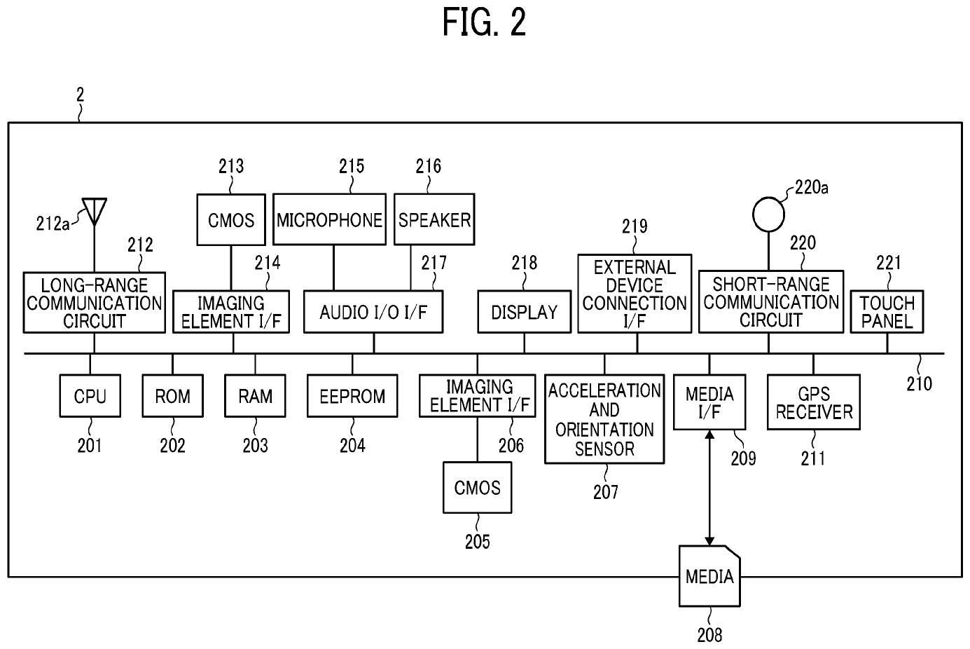

Next, referring to FIGS. 2 to 4, hardware configurations of the smartphone 2, the smart meter 3, the intermediary server 5, and the node 9 are described according to the embodiment.

### Hardware Configuration of Smartphone:

FIG. 2 is a schematic diagram illustrating a hardware configuration of a smartphone according to the exemplary embodiment. As illustrated in FIG. 2, the smartphone 2 includes a central processing unit (CPU) 201, a read only memory (ROM) 202, a random access memory (RAM) 203, an Electrically Erasable Programmable ROM (EEPROM) 204, a Complementary Metal Oxide Semiconductor (CMOS) sensor 205, an image element interface (IT) 206, an acceleration and orientation sensor 207, a media I/F 209, and a Global Positioning System (GPS) receiver 211.

The CPU 201 controls entire operation of the smartphone 2. The ROM 202 stores a control program for operating the CPU 201 such as an Initial Program Loader (IPL). The RAM 203 is used as a work area for the CPU 201. The EEPROM 204 reads or writes various data such as a control program for a smartphone under control of the CPU 201. The CMOS sensor 205 is an example of a built-in imaging device that captures an object (mainly, a self-image of a user operating the smartphone 2) under control of the CPU 201 to obtain image data. In alternative to the CMOS sensor 205, an imaging element such as a charge-coupled device (CCD) sensor can be used. The imaging element I/F 206 is a circuit that controls driving of the CMOS sensor 205. The acceleration and orientation sensor 207 includes various sensors such as an electromagnetic compass or gyrocompass for detecting geomagnetism and an acceleration sensor. The media I/F 209 controls reading and writing (storing) of data from and to a storage medium (media) 208 such as a flash memory. The GPS receiver 211 receives a GPS signal from a GPS satellite.

The smartphone 2 further includes a long-range communication circuit 212, a CMOS sensor 213, an imaging element I/F 214, a microphone 215, a speaker 216, an audio input/output I/F 217, a display 218, an external device connection I/F 219, a short-range communication circuit 220, an antenna 220a for the short-range communication circuit 220, and a touch panel 221.

The long-range communication circuit 212 is a circuit that enables the smartphone 2 to communicate with other device through the communication network 100. The CMOS sensor 213 is an example of a built-in imaging device that captures an object under control of the CPU 201 to obtain image data. The imaging element I/F 214 is a circuit that controls driving of the CMOS sensor 213. The microphone 215 is a built-in circuit that converts audio into an electric signal. The speaker 216 is a built-in circuit that generates audio such as music or voice by converting an electric signal into physical vibration. The audio input/output I/F 217 is a circuit for inputting or outputting an audio signal between the microphone 215 and the speaker 216 under control of the CPU 201. The display 218 is an example of a display device that displays an image of the object, various icons, etc. Examples of the display 218 include a liquid crystal display (LCD) and an organic electroluminescence (EL) display. The external device connection I/F 219 is an interface that connects the smartphone 2 to various external devices. The short-range communication circuit 220 is a communication circuit that communicates in compliance with the near field communication (NFC), the Bluetooth, and the like. The touch panel 221 is an example of an input device that allows a user to operate the smartphone 2 by touching a screen of the display 218.

The smartphone 2 further includes a bus line 210. The bus line 210 is an address bus or a data bus that electrically connects the elements illustrated in FIG. 2, such as the CPU 201, to each other.

### Hardware Configuration of Smart Meter:

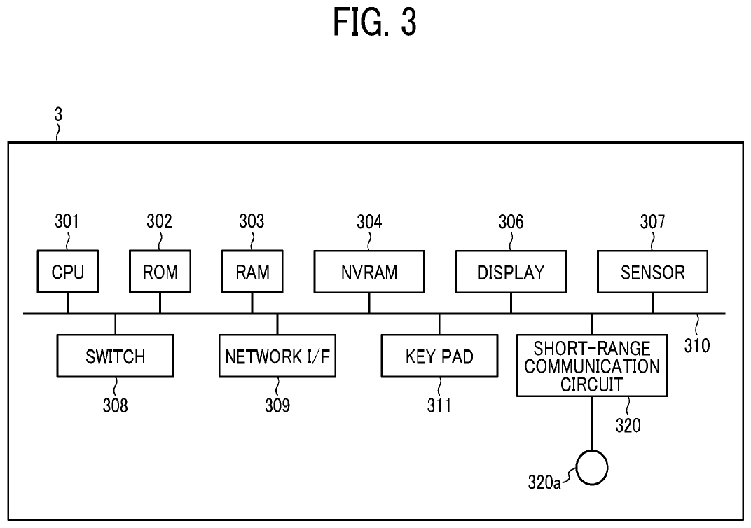

FIG. 3 is a schematic diagram illustrating an example of hardware configuration of the smart meter according to the exemplary embodiment. As illustrated in FIG. 3, the smart meter 3 is provided with a computer. Still referring to FIG. 3, the smart meter 3 includes a CPU 301, ROM 302, RAM 303, non-volatile random access memory (NVRAM) 304, display 306, measurement sensor 307, switch 308, network I/F 309, keypad 311, touch panel 312, short-range communication circuit 320, and antenna 320a for the short-range communication circuit 320.

The CPU 301 controls entire operation of the smart meter 3. The ROM 302 stores a control program for driving the CPU 301 such as an IPL. The RAM 303 is used as a work area for the CPU 301. The NVRAM 304 is a non-volatile memory that stores and reads various data such as the control program. The display 306 displays various information such as a cursor, a menu, a window, a character, or an image.

The measurement sensor 307 measures electricity provided or consumed by the smart meter 3. The switch 308 is turned on to close, or turned off to open, the connections in an electric circuit to cause the electric current flow or stop in the electric circuit in the smart meter 3.

The network I/F 309 is an interface for communicating data via the communication network 100 including the blockchain network 90 such as the Internet. The keypad 311 is an example of input device provided with a plurality of keys for inputting or selecting characters, numerals, or various instructions. The short-range communication circuit 320 is a communication circuit that enables communication based on short-range wireless technology such as NFC and Bluetooth. The bus line 310 is an address bus or a data bus, which electrically connects the hardware resources illustrated in FIG. 3 such as the CPU 301.

### Hardware Configuration of Intermediary Server:

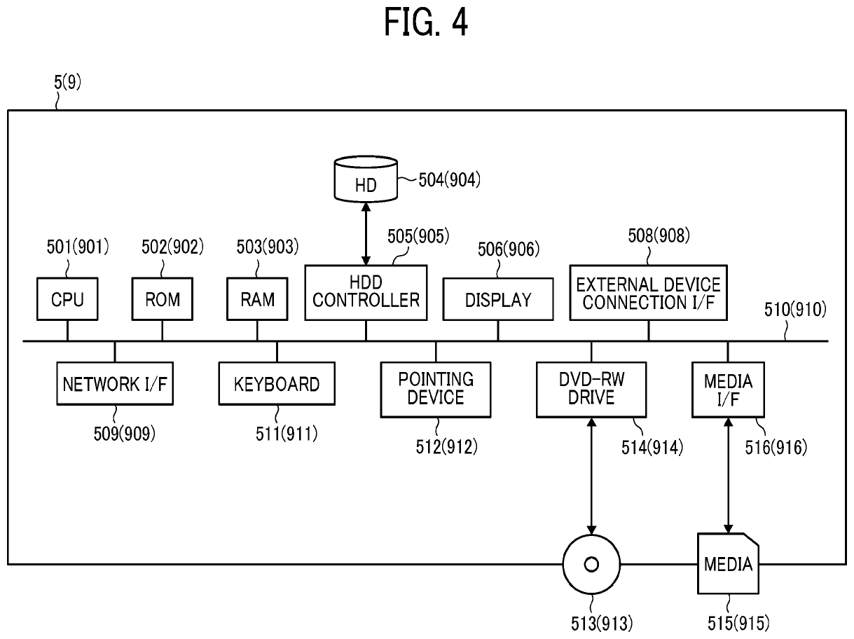

FIG. 4 is a schematic diagram illustrating a hardware configuration of the intermediary server according to the exemplary embodiment. Hardware components of the intermediary server 5 are designated by reference numerals in 500 series. As illustrated in FIG. 4, the intermediary server 5 is implemented by a computer. Specifically, the intermediary server 5 of FIG. 4 includes a CPU 501, ROM 502, RAM 503, hard disk (HD) 504, hard disk drive (HDD) controller 505, display 506, external device connection I/F 508, network I/F 509, bus line 510, keyboard 511, pointing device 512, Digital Versatile Disk Rewritable (DVD-RW) drive 514, and media I/F 516.

The CPU 501 controls entire operation of the intermediary server 5. The ROM 502 stores a control program for driving the CPU 501, such as an IPL. The RAM 503 is used as a work area for the CPU 501. The HD 504 stores various data such as a program. The HDD controller 505 controls reading and writing of various data from and to the HD 504 under control of the CPU 501. The display 506 displays various information such as a cursor, a menu, a window, a character, or an image. The external device connection I/F 508 is an interface for connecting to various external devices. Examples of the external devices include, but not limited to, a universal serial bus (USB) memory and a printer. The network I/F 509 is an interface that controls communication of data with an external device through the communication network 100. The bus line 510 is, for example, an address bus or a data bus, which electrically connects the elements such as the CPU 501 illustrated in FIG. 4.

The keyboard 511 is an example of an input device provided with a plurality of keys for allowing a user to input characters, numerals, or various instructions. The pointing device 512 is an example of an input device that allows a user to select or execute a specific instruction, select a target for processing, or move a cursor being displayed. The DVD-RW drive 514 reads and writes various data from and to a DVD-RW 513, which is an example of a removable storage medium. The removable storage medium is not limited to the DVD-RW and may be a digital versatile disc-recordable (DVD-R) or Blu-ray Disc. The medium I/F 516 controls reading and writing (storing) of data from and to the storage medium 515 such as a flash memory.

### Hardware Configuration of Node:

FIG. 4 is a schematic diagram also illustrating an example of hardware configuration of the node. Hardware components of the node 9 are designated by reference numerals in 900 series. As illustrated in FIG. 4, since the node 9, which is implemented by a computer, has the same configuration as the intermediary server 5, description of hardware configuration thereof is omitted.

### Functional Configuration:

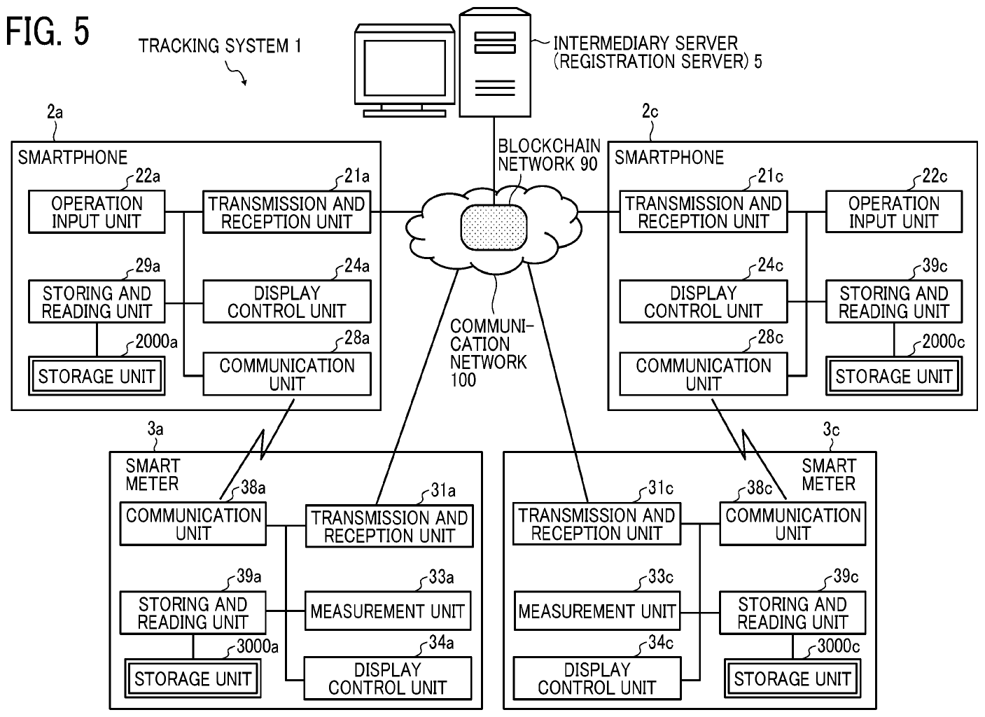

Next, referring to FIGS. 5 to 8, a functional configuration of each terminal and device of the tracking system 1 is described according to the embodiment. FIG. 5 is a schematic block diagram illustrating an example functional configuration of the smartphone and the smart meter in the tracking system.

### Functional Configuration of Smartphone 2a:

As illustrated in FIG. 5, the smartphone 2a includes a transmission and reception unit 21a, an operation input unit 22a, a display control unit 24a, a communication unit 28a, and a storing and reading unit 29a. These units are caused to function by operating one or more hardware components illustrated in FIG. 2 in cooperation with instructions of the CPU 201 according to the control program for smartphone loaded from the EEPROM 204 to the RAM 203.

Further, the smartphone 2a includes a storage unit 2000a implemented by the ROM 202, the RAM 203, and the EEPROM 204 illustrated in FIG. 2.

### Functional Units of the Smartphone 2a:

The transmission and reception unit 21a of the smartphone 2a, which is implemented mainly by instructions of the CPU 201 with respect to the long-range communication circuit 212, controls transmission or reception of various data (or information) to or from other device (for example, the intermediary server 5) via the communication network 100.

The operation input unit 22a, which is mainly implemented by instructions of the CPU 201 with respect to the touch panel 221, receives various selections or inputs from the user.

The display control unit 24a, which is mainly implemented by instructions of the CPU 201, controls the display 218 to display various images. The display control unit 24a further provides a web browser function.

The communication unit 28a, which is mainly implemented by instructions of the CPU 201 with respect to the short-range communication circuit 220, communicates various data with a communication unit 38a, to be described later, of the smart meter 3a. In the case of wired communication, the smartphone 2 is connected to the smart meter 3a via a communication cable to communicate data.

The storing and reading unit 29a, which is mainly implemented by instructions of the CPU 201, stores various data (or information) in the storage unit 2000a and reads various data (or information) from the storage unit 2000a.

### Functional Configuration of Smartphone 2c:

As illustrated in FIG. 5, the smartphone 2c includes a transmission and reception unit 21c, an operation input unit 22c, a display control unit 24c, a communication unit 28c, and a storing and reading unit 29c. These units are caused to function by operating one or more hardware components illustrated in FIG. 2 in cooperation with instructions of the CPU 201 according to the control program for smartphone loaded from the EEPROM 204 to the RAM 203.

Further, the smartphone 2c includes a storage unit 2000c implemented by the ROM 202, the RAM 203, and the EEPROM 204 illustrated in FIG. 2.

The respective units of the smartphone 2c (transmission and reception unit 21c, operation input unit 22c, display control unit 24c, communication unit 28c, and storing and reading unit 29c) are substantially the same in function to corresponding units of the smartphone 2a (transmission and reception unit 21a, operation input unit 22a, display control unit 24a, communication unit 28a, and storing and reading unit 29a), so that description thereof is omitted.

Similarly to the smartphone 2c, the smartphone 2b is substantially the same in function to the smartphone 2a, but FIG. 5 omits the smartphone 2b as the smartphone 2b is not referred below.

### Functional Configuration of Smart Meter 3a:

As illustrated in FIG. 5, the smart meter 3a includes a transmission and reception unit 31a, a measurement unit 33a, a display control unit 34a, a communication unit 38a, and a storing and reading unit 39a. These units are caused to function by operating one or more hardware components illustrated in FIG. 3 in cooperation with instructions of the CPU 301 according to the control program for smart meter loaded from the NVRAM 304 to the RAM 303. Further, the smart meter 3a includes a storage unit 3000a implemented by the ROM 302, the RAM 303, and the NVRAM 304 illustrated in FIG. 3.

### Functional Units of The Smart Meter 3a:

The transmission and reception unit 31a of the smart meter 3a, which is implemented mainly by instructions of the CPU 301 with respect to the network I/F 309, controls transmission or reception of various data (or information) to or from other device (for example, the intermediary server 5) via the communication network 100.

The measurement unit 33a, which is implemented mainly by instructions of the CPU 301 with respect to the measurement sensor 307, measures the amount of electricity generated by the power generator 4a.

The display control unit 34a, which is mainly implemented by the instructions of the CPU 301, controls the display 306 to display various images.

The communication unit 38a, which is mainly implemented by the instructions of the CPU 301 with respect to the short-range communication circuit 320, communicates various data with the communication unit 28a of the smartphone 2a. In the case of wired communications, a communication cable is connected to the smart meter 3a for the data communication.

The storing and reading unit 39a, which is mainly implemented by instructions of the CPU 301, stores various data (or information) in the storage unit 3000a and reads various data (or information) from the storage unit 3000a.

### Functional Configuration of Smart Meter 3c:

As illustrated in FIG. 5, the smart meter 3c includes a transmission and reception unit 31c, a measurement unit 33c, a display control unit 34c, a communication unit 38c, and a storing and reading unit 39c. These units are caused to function by operating one or more hardware components illustrated in FIG. 3 in cooperation with instructions of the CPU 301 according to the control program for smart meter loaded from the NVRAM 304 to the RAM 303.

Further, the smart meter 3a includes a storage unit 3000c implemented by the ROM 302, the RAM 303, and the NVRAM 304 illustrated in FIG. 3.

The respective units of the smart meter 3c (transmission and reception unit 31c, measurement unit 33c, display control unit 34c, communication unit 38c, and storing and reading unit 39c) are substantially the same in function to corresponding units of the smart meter 3a (transmission and reception unit 31a, measurement unit 33a, display control unit 34a, communication unit 38a, and storing and reading unit 39a), so that description thereof is omitted.

Similarly to the smart meter 3c, the smart meter 3b is substantially the same in function to the smart meter 3a, but FIG. 5 omits the smart meter 3b as the smart meter 3b is not referred in the following description.

### Functional Configuration of Intermediary Server 5:

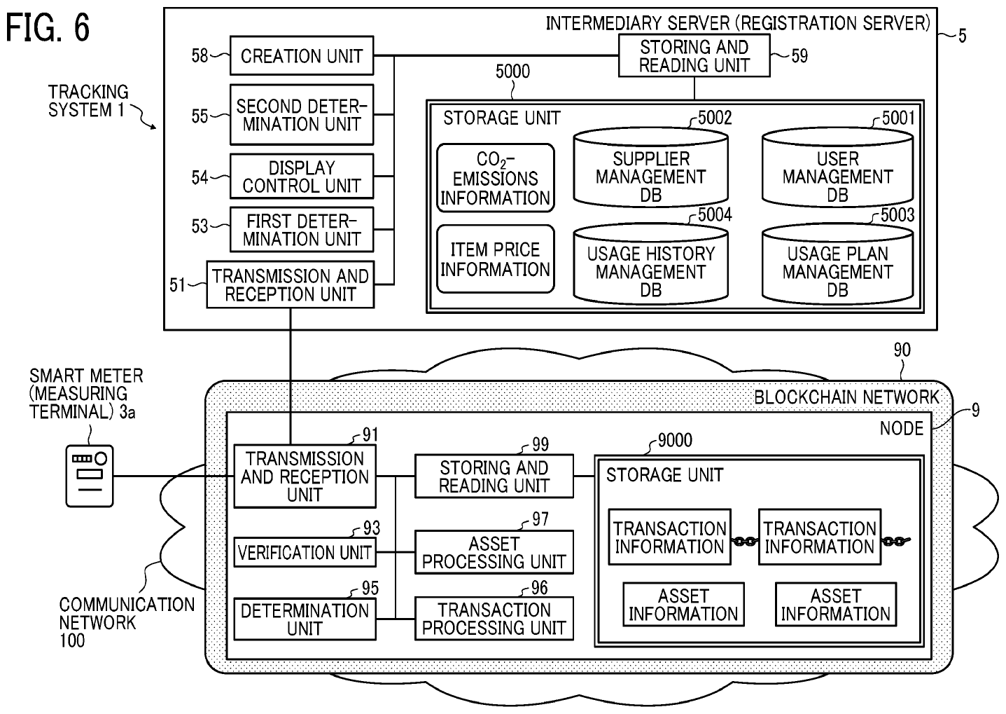

For simplicity, FIG. 6 also illustrates a block diagram of a functional configuration of the intermediary server 5. FIG. 6 is a schematic block diagram illustrating a functional configuration of the intermediary server and the node in the tracking system according to the exemplary embodiment. As illustrated in FIG. 6, the intermediary server 5 includes a transmission and reception unit 51, a first determination unit 53, a display control unit 54, a second determination unit 55, a creation unit 58, and a storing and reading unit 59. These units are caused to function by operating one or more hardware components illustrated in FIG. 4 in cooperation with instructions of the CPU 501 according to the control program for the intermediary server loaded from the HD 504 to the RAM 503.

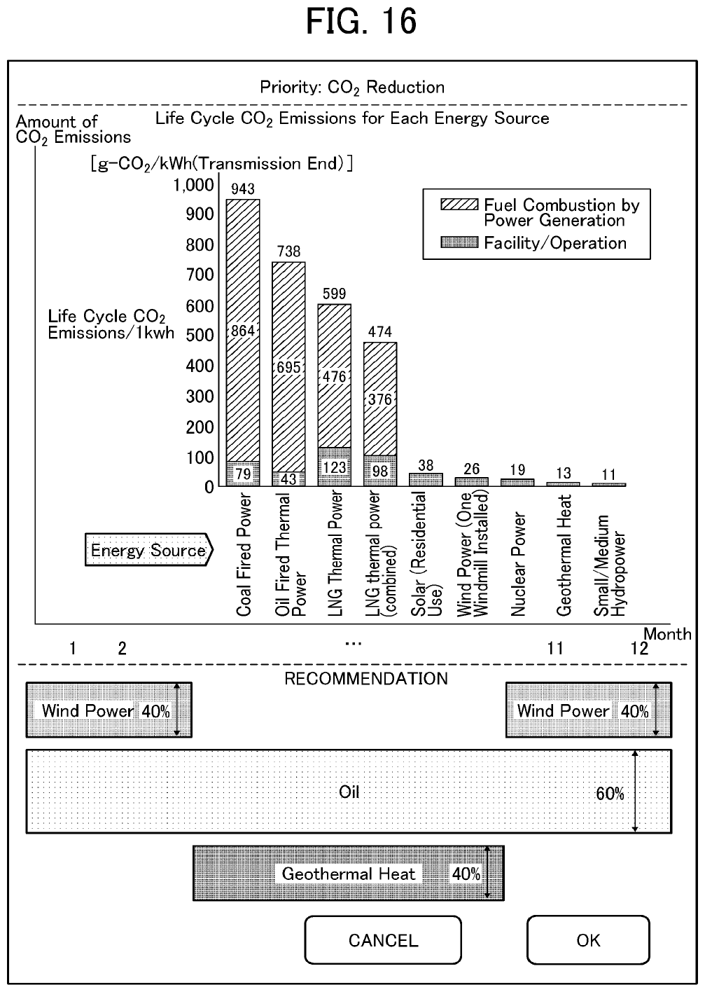

Further, the intermediary server 5 includes a storage unit 5000 implemented by the ROM 502 and the HD 504 illustrated in FIG. 4. The storage unit 5000 stores carbon dioxide emission amount information to be used for a graph of life cycle CO2 emissions for each power source of FIG. 16. The carbon dioxide emission amount information may be referred to as carbon dioxide emissions information, or CO2-emissions information. The storage unit 5000 further stores item price information indicating a past monthly item price and an expected monthly item price in the next year for each production method. As for the past price (past monthly item price), the past prices of at least one year or more from a current month is indicated.

### User Management Table

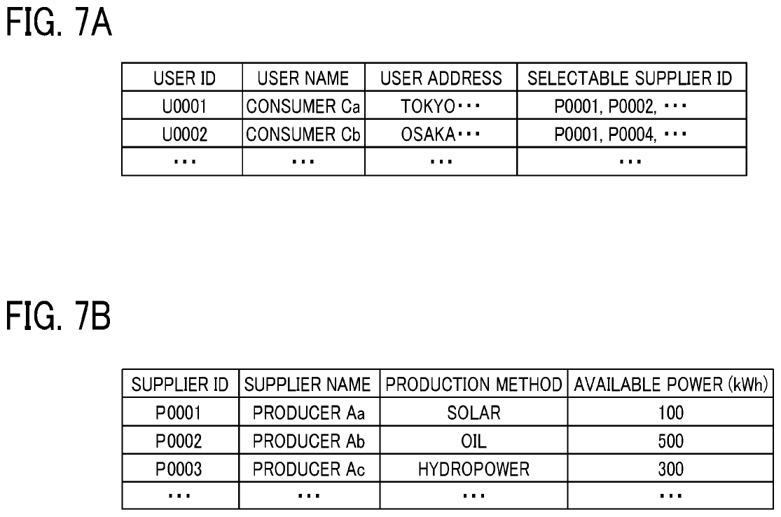

FIG. 7A is a conceptual diagram illustrating an example of user management table. The user management table is a table used by the intermediary agent Da to manage information on each user such as a consumer of electricity. Specifically, the storage unit 5000 includes a user management database (DB) 5001, such as a user management table as illustrated in FIG. 7A. The user management table stores, for each user, a user ID, a user name, a user's address (or location where the user resides), and a selectable supplier ID in association.

Of these items, the user ID is an example of user identification information for identifying the user of an asset, such as the consumer Ca of electricity. The selectable supplier ID is an example of supplier identification information for identifying a supplier, such as a producer of electricity, which can be selected by the user identified with the user ID. For example, if the user's address is in Tokyo, the selectable suppliers are limited to those suppliers that have addresses in or around Tokyo.

### Supplier Management Table

FIG. 7B is a conceptual diagram illustrating an example of supplier management table. The supplier management table is a table used by the intermediary agent Da to manage each supplier such as a producer of electricity. The storage unit 5000 stores a supplier management DB 5002, which is implemented by the supplier management table as illustrated in FIG. 7B. The supplier management table includes, for each supplier, a supplier ID, a supplier name, an asset (such as electricity) production method of the supplier, and an amount of asset that can be supplied from the supplier, in association.

Of these items, the supplier ID is an example of supplier identification information for identifying the supplier of asset such a producer of electricity. The production method is determined based on a type of energy resource used to produce the asset (electricity). As described above, examples of production method include a production method using solar (solar light or solar heat), a production method using wind power, a production method using biomass, a production method using geothermal power, a production method using hydroelectric power, a production method using oil, a production method using coal, and a production method using liquefied natural gas. The above-described production methods may be classified into one or more groups, such as the group of production methods using renewable energy source or the group of production methods using conventional energy such as fossil fuel. The amount that can be supplied is an amount of assets that can be supplied by a supplier for a certain time period. In case the supplier is a producer of electricity, the amount that can be supplied is an amount of electric energy that can be supplied for a unit of time (here, one hour) (kWh).

### Usage Plan Management Table:

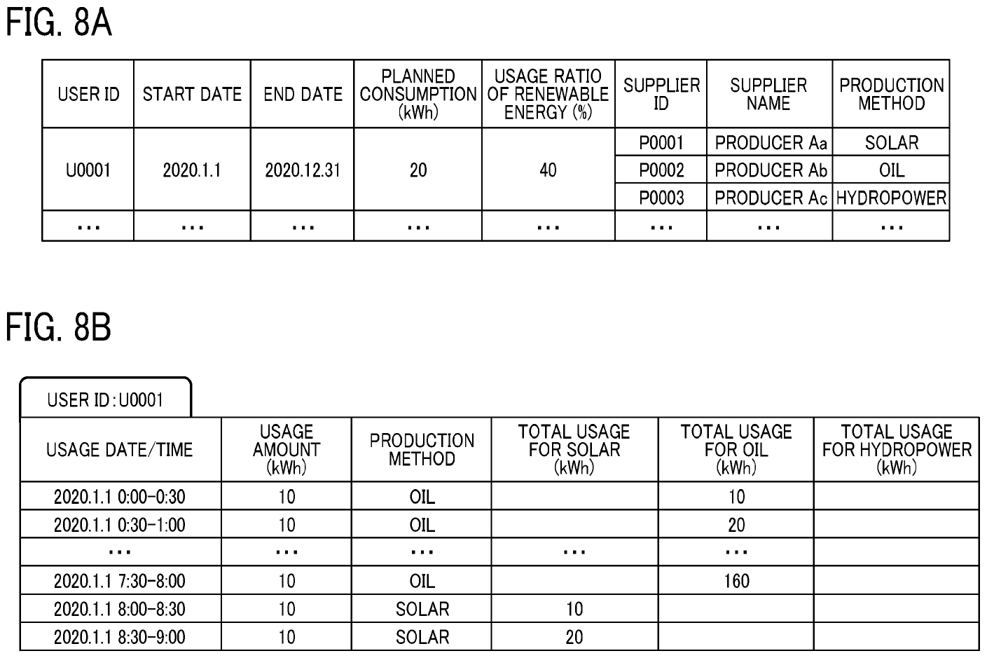

FIG. 8A is a conceptual diagram illustrating an example of usage plan management table. The usage plan management table is a table used for managing information on planned usage of asset, set by the user such as the consumer Ca. The storage unit 5000 includes a usage plan management DB 5003, which is implemented by the usage plan management table as illustrated in FIG. 8A. The usage plan management table includes information on details of usage that the user previously sets for future. Here, the example case in which the asset is electricity is described. Specifically, the usage plan management table includes a user ID of a user, usage start date, usage end date, planned usage amount (planned energy consumption), renewable energy usage ratio, supplier ID of a supplier, a supplier name of the supplier, and production method of asset, in association. The same data items stored both in the tables of FIGS. 7A and 7B, such as the user ID, are each designated with the same item name.

Of these, the usage start date is information indicating the date when the user such as the consumer Ca starts using the asset such as electricity. The usage end date is information indicating the date when the user ends using the asset such as electricity. The planned usage amount is the amount of asset that the user plans to use for a certain time period, and can be expressed in terms of electric energy (kWh). The renewable energy usage ratio is information indicating a ratio (%) of assets (electricity) produced from renewable energy source such as solar light, with respect to total amount of assets (electricity) to be used by the user such as the consumer Ca during a certain time period such as a period between the start date and the end date.

### Usage History Management Table:

FIG. 8B is a conceptual diagram illustrating an example of usage history management table. The usage history management table is a table for managing, for each user such as the consumer Ca, a history (log) of usage of asset that the intermediary server 5 transfers its ownership from the supplier to the user. The storage unit 5000 includes a usage history management DB 5004, such as the usage history management table as illustrated in FIG. 8B for each user. The usage history management table manages usage history information, specifically, the usage date and time, the usage amount, the production method of asset in use, and the total (accumulated) usage amount (consumption) by production method, in association. Specifically, in the description of the exemplary embodiment, the usage history management table manages a log of electricity consumption for each user by production method. From this perspective, the usage history management table of FIG. 8B indicates the date and time of electricity consumption, the amount of electricity consumption, the production method of electricity being consumed, and the total amount of electricity consumption by production method. The production method is determined based on a type of resource (such as an energy resource) used to produce asset (such as electricity). For example, when the asset is electricity, one example of production method corresponds to one or more processes of producing electricity from solar such as solar light using various technologies. Although this embodiment describes a case in which one production method uses solar light and another production method uses oil, any other type of production method (for example, production method using wind power or production method using coal) may be used. Further, the above-described production methods may be classified into one or more groups, such as the group of production methods using renewable energy source or the group of production methods using conventional energy such as fossil fuel.

Of the usage history information, the same data items stored in the tables of FIGS. 7A and 7B, such as the user ID, are each designated with the same item name. In this example, the usage date and time indicates the date and time when ownership of asset is transferred, specifically, the date and time when the intermediary server 5 transfers the ownership of the asset acquired from the supplier, such as the producer, to the user such as the consumer Ca. The usage amount indicates an amount of asset that the intermediary server 5 acquires from the supplier and provides to the user. In this example case, the amount of asset, which is electricity, is represented by, for example, electric energy (kWh). The total usage amount indicates a total amount of assets, which are produced by a specific production method and allocated to a user such as the consumer Ca for a certain period of time, and is expressed in total electric energy (kWh), for example. Before transfer of ownership of asset, the intermediary server 5 refers to a record of the user in the usage history management DB 5004 to determine a production method of asset to be allocated to the user such as the consumer Ca. For example, when the renewable energy usage ratio set by the consumer Ca is 40% as illustrated in FIG. 8A, the intermediary server 5 refers to the total usage amount for solar in the usage history management DB 5004, to determine a production method of asset to be provided to the consumer Ca.

In this example, since the planned usage amount (for example, 20 kWh) illustrated in FIG. 8A is a planned usage amount for every hour, the usage amount will be half the planned usage amount (for example, 10 kWh), when transferring the ownership of asset is performed every 30 minutes as illustrated in FIG. 8B.

Although this embodiment describes a case in which one production method uses solar light and another production method uses oil, any other type of production method (for example, production method using wind power or production method using coal) may be used. Further, the above-described production methods may be classified into one or more groups, such as the group of production methods using renewable energy source or the group of production methods using conventional energy source such as fossil fuel.

Furthermore, the production method may be determined based on a type of asset production process. When any one of processes in producing the asset such as electricity differs, the asset production processes are different, such that the production methods differ from each other. In one example, even when the same energy resource, such as solar, is used to produce electricity, if different technologies used for producing electricity (such as one using solar light and other using solar heat) differ, the resultant processes are different such that they belong to different production methods. In another example, if different machines are used or not used (such as a case when a turbine is used, or not used, to produce electricity), the resultant processes are different such that they belong to different production methods.

### Functional Units of Intermediary Server:

Next, each function unit of the intermediary server 5 is described in detail with reference to FIG. 6, according to the embodiment. The transmission and reception unit 51 of the intermediary server 5, which is implemented mainly by instructions of the CPU 501 with respect to the network I/F 509, controls transmission or reception of various data (or information) to or from other device (for example, the smartphone 2a, 2c) via the communication network 100. The transmission and reception unit 51 also serves as a reception unit that receives the planned usage, described later, from the smartphone 2c.

The first determination unit 53, which is implemented by the instructions of the CPU 501, determines asset information indicating an ownership of the asset (the asset that the intermediary server 5 intermediates transfer of ownership) to be transferred to the user. For example, it is assumed that the intermediary agent Da intermediates transfer of ownership of asset, produced by a specific type of production method, for the consumer Ca. In such case, the first determination unit 53 determines asset information on such asset, based on “history of usage of asset produced by the specific type of production method for a specific user (customer Ca)” stored in the usage history management DB 5004, and “renewable energy usage ratio” stored in the usage plan management DB 5003. Specifically, when the renewable energy usage ratio for the consumer Ca is set to 40%, the first determination unit 53 refers to the total usage amount of solar in the usage history management DB 5004, to determine to transfer ownership of asset produced from renewable energy source, from the intermediary agent Da (managing the intermediary server 5) to the consumer Ca, until the renewable energy usage ratio reaches 40%.

The display control unit 54, which is mainly implemented by the instructions of the CPU 501, controls the display 506 to display various images, or controls the display 218 of the smartphone 2 to display various images via the communication network 100. In this case, the smartphone 2 displays various images using functions provided by the web browser of the display control unit 24 of the smartphone 2. The display control units 24a and 24c may be collectively referred to as the display control unit 24.

The second determination unit 55, which is implemented by the instructions of the CPU 501, makes various determinations.

The creation unit 58, which is implemented by the instructions of the CPU 501, creates an application form to be submitted by the intermediary agent to the certification authority E, based on the transaction information and the asset information. This application form is a predetermined application form, which is used to apply for a production method certificate, certifying that the asset is produced by a certain type of production method.

The storing and reading unit 59, which is mainly implemented by the instructions of the CPU 501, stores various data (or information) in the storage unit 5000 and reads various data (or information) from the storage unit 5000.

### Functional Configuration of Node 9:

As illustrated in FIG. 6, the node 9 includes a transmission and reception unit 91, a verification unit 93, a determination unit 95, a transaction processing unit 96, an asset processing unit 97, and a storing and reading unit 99. These units are caused to function by operating one or more hardware components illustrated in FIG. 4 in cooperation with instructions of the CPU 901 according to the control program for the node loaded from the HD 904 to the RAM 903.

The node 9 further includes a storage unit 9000, which is implemented by the ROM 902 and the HD 904 illustrated in FIG. 4. For descriptive purposes, FIG. 6 illustrates a state in which transaction information is connected like a chain. The node 9 further stores asset information generated based on the transaction information. The transaction information and the asset information are stored in each node.

### Function Units of Node:

Next, each functional unit of the node 9 is described in detail with reference to FIG. 6. The transmission and reception unit 91 of the node 9, which is implemented mainly by instructions of the CPU 901 with respect to the network I/F 909, controls transmission or reception of various data (or information) to or from other node of the blockchain network 90 on the communication network 100. The transmission and reception unit 91 transmits or receives various data (or information) between the transmission and reception unit 31a of the smart meter 3a and the transmission and reception unit 51 of the intermediary server 5. Although the smart meter 3b is not illustrated in FIG. 6, the transmission and reception unit 91 actually transmits or receives various data (or information) to or from the smart meter 3b.

The verification unit 93, which is implemented by the instructions of the CPU 901, verifies the certificate and the provided information. The certificate verification is a process of determining whether or not a target certificate is a certificate of the entity that is registered in advance in the node 9. The verification of the provided information is a process of determining whether or not all predetermined contents are entered in predetermined format (for example, whether the supplier is entered or the provision time period is entered).

The determination unit 95, which is implemented by the instructions of the CPU 901, makes various determinations.

The transaction processing unit 96, which is implemented by the instructions of the CPU 901, performs processing such as generating transaction information indicating a transaction causing generation of asset information and storing the transaction information in the storage unit 9000.

The asset processing unit 97, which is implemented by the instructions of the CPU 901, performs processing such as generating asset information according to the transaction information and storing the asset information in the storage unit 9000.

The storing and reading unit 99, which is mainly implemented by the instructions of the CPU 901, stores various data (or information) in the storage unit 9000 and reads various data (or information) from the storage unit 9000.

### Processes or Operation:

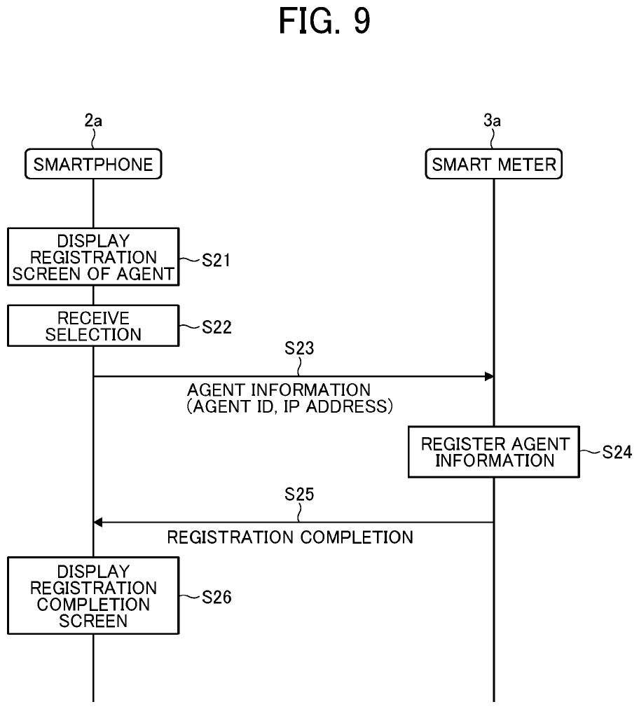

Referring to FIGS. 9 to 21, operation of managing image types to be processed, performed by the tracking system 1 (system for managing energy consumption), is described according to the embodiment.

### Registration of Intermediary Agent:

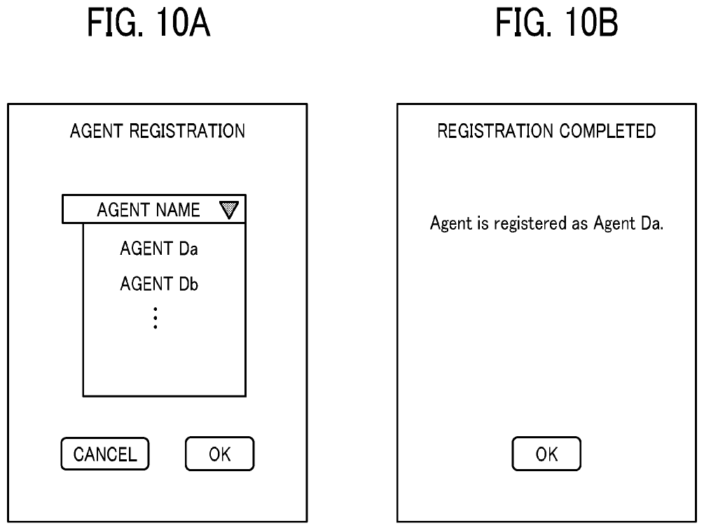

Next, referring to FIGS. 9 and 10, processing of registering intermediary agents is described according to the exemplary embodiment. FIG. 9 is a sequence diagram illustrating example processing of registering intermediary agents. FIG. 10A is an illustration of an example intermediary agent registration screen. FIG. 10B is an illustration of an example intermediary agent registration completion screen. The following describes an example case in which the producer Aa registers the intermediary agent Da, from among a plurality of intermediary agents. It is assumed that the producer Aa previously makes a contract with the intermediary agent Da, such that the producer Aa is able to select the intermediary agent Da as described later. The smartphone 2a is installed with an application program that allows the producer Aa to register intermediary agents. This application program allows the smartphone 2a to obtain various information on each intermediary agent, such as an intermediary agent ID for identifying the intermediary agent, a name of the intermediary agent, and an internet protocol (IP) address of an intermediary server of the intermediary agent, which are stored in association.

As illustrated in FIG. 9, at the smartphone 2a, the display control unit 24a controls the display 218 to display the intermediary agent registration screen illustrated in FIG. 10A (S21). The intermediary agent registration screen displays a pull-down menu, which lists a plurality of intermediary agent names to allow the producer Aa to select a particular intermediary agent. The intermediary agent registration screen further includes, at its lower part, an “OK” button to be pressed to confirm the intermediary agent name selected from the pull-down menu, and a “CANCEL” button to be pressed to cancel the selection.

When the producer Aa selects a desired intermediary agent name from the plurality of intermediary agent names and presses the “OK” button, the operation input unit 22a receives the selection on the intermediary agent (S22). Here, the case where the intermediary agent Da is selected is described.

After the operation input unit 22a receives the selection, the communication unit 28a transmits information on the selected intermediary agent to the communication unit 38a of the smart meter 3a by short-range wireless communication (S23). The intermediary agent information includes an intermediary agent ID for identifying the selected intermediary agent and an IP address of an intermediary server of the selected intermediary agent. Accordingly, the communication unit 38a of the smart meter 3a receives the intermediary agent information.

Next, at the smart meter 3a, the storing and reading unit 39a registers the intermediary agent information in the storage unit 3000a (S24). With this information on the registered agent, the smart meter 3a is able to communicate with the intermediary server 5 of the registered agent to request various processing. Then, the communication unit 38a transmits registration completion information indicating that registration of the intermediary agent is completed to the smartphone 2a (S25). Accordingly, the communication unit 28a of the smartphone 2a receives the registration completion information.

Next, at the smartphone 2a, the display control unit 24a controls the display 218 to display the registration completion screen as illustrated in FIG. 10B (S26). The registration completion screen displays a message indicating that registration of the intermediary agent is completed. The registration completion screen further includes an “OK” button to be pressed by the producer Aa to close the screen being displayed. When the producer Aa presses the “OK” button, the registration completion screen is closed.

The processing of registering the intermediary agent thus ends.

### Registration of Usage Plan:

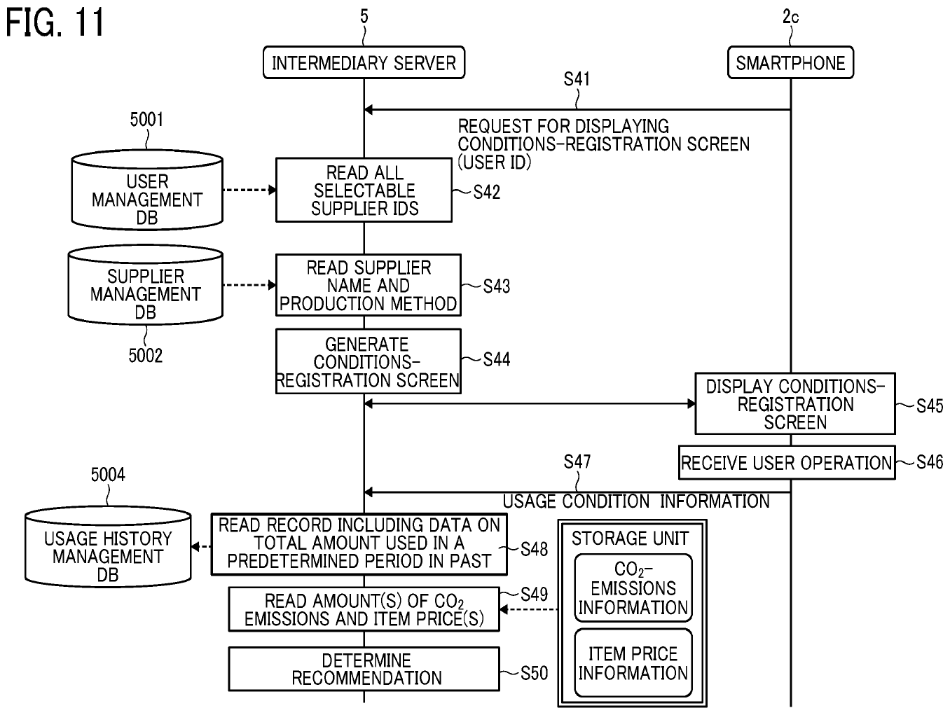

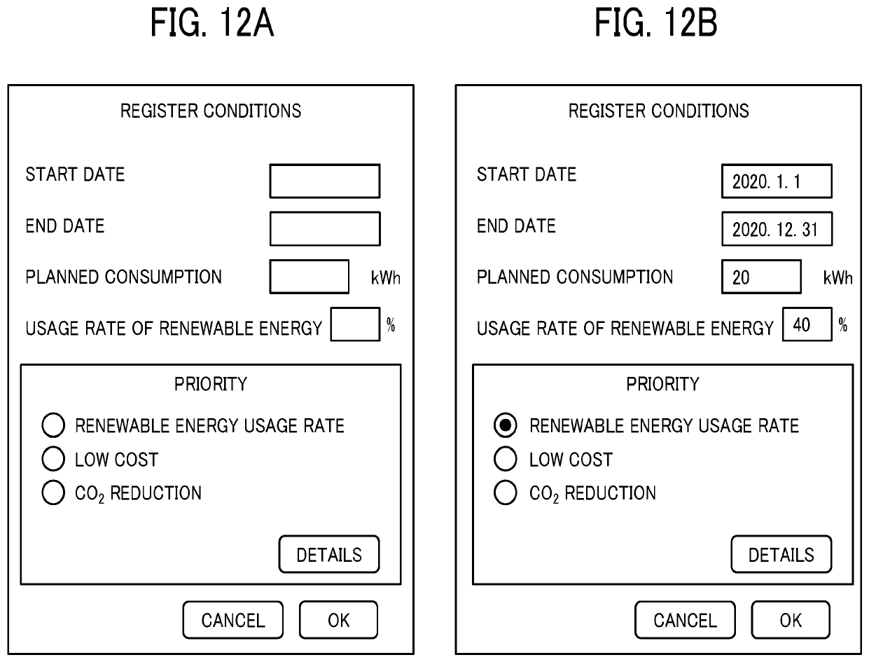

Next, referring to FIGS. 11 to 16, processing of registering usage plan, namely a plan for future energy consumption, is described according to the exemplary embodiment. FIG. 11 is a sequence diagram illustrating processing of registering usage conditions for an item (asset) according to the embodiment. Namely, the usage conditions are conditions related to future energy consumption, in the exemplary embodiment. In the exemplary embodiment, electricity is used as an example of the item (asset). FIG. 12A is an illustration of an example usage conditions registration screen before information is entered or selected. FIG. 12B is an illustration of an example usage conditions registration screen after information is entered or selected. The following describes the example case in which the consumer Ca registers the usage plan, or the plan for future energy consumption, for electricity, as an item (asset), to the intermediary server 5 using the smartphone 2c.

As illustrated in FIG. 11, the transmission and reception unit 21c of the smartphone 2c transmits a request (display request) for displaying a usage conditions registration screen to the intermediary server 5 via the communication network 100 (S41). The display request includes a user ID for identifying the consumer Ca as a user who is the request source. Accordingly, the transmission and reception unit 51 of the intermediary server 5 receives the display request. The user ID is an example of user identification information. When the user is an individual, examples of the user identification information include any number for uniquely identifying an individual, which may be designated by a public institution such as a social security number in the U.S., a my number in Japan, and a telephone number of the individual. When the user is an organization such as a company, examples of the user identification information include any number for uniquely identifying a company, such as a telephone number of the company.

Next, at the intermediary server 5, the storing and reading unit 59 searches the user management DB 5001 (see FIG. 7A) using the user ID received at S41 as a search key, to read out all selectable supplier IDs associated with the user ID (S42). Further, the storing and reading unit 59 searches the supplier management DB 5002 using each supplier ID read at S42 as a search key, to read out various information on each supplier (supplier name, production method, and amount that can be supplied) (S43). The display control unit 54 generates a usage conditions registration screen (conditions-registration screen) as illustrated in FIG. 12A based on the information read at S43 (S44). Accordingly, at the smartphone 2c, the display control unit 24c uses its web browser function to display, on the display 218 of the smartphone 2c, the usage conditions registration screen illustrated in FIG. 12A, which is generated by the intermediary server 5 (S45). The usage conditions registration screen may be generated at the smartphone 2c, by using its web browser function, based on the information received from the intermediary server 5. Alternatively, an application (“app”) installed on the smartphone 2c may perform the same functions as the web browser function described throughout this application. The usage conditions registration screen includes a plurality of fields for entering usage start date, usage end date, planned usage amount (planned energy consumption), and renewable energy usage ratio (usage rate of renewable energy), and a section for selecting a matter of priority for setting the planned usage. The renewable energy usage ratio indicates a ratio of electricity produced from renewable energy source to total electricity, which is planned to be used by the consumer Ca. The entered or selected conditions including the matter of priority are to be used by the intermediary server 5 to determine a recommendation including one or more types of recommended production methods. The type of production method includes an energy type.

In the section for selecting a matter of priority, a plurality of matters of priority and a detail setting button (a “DETAILS” button) are displayed. A selected matter of priority is to be used for determining a recommendation for the future energy consumption. Further, for each of the plurality of matters of priority, a radio button for accepting the selection of a specific matter of priority among the plurality of matters of priority is displayed. The intermediary server 5 transfers one or more ownerships of electricity from among the ownerships each of which has a different type of production method, according to the selected matter of priority. In the embodiment, as examples of the matters of priority, “achieving a renewable energy usage ratio (“RENEWABLE ENERGY USAGE RATE”)”, “achieving the lowest cost (“LOW COST”)”, and “minimizing oxygen dioxide emissions (“CO2 REDUCTION”)” are used. In FIG. 12A, these are simply illustrated as “RENEWABLE ENERGY USAGE RATE”, “LOW COST”, and “CO2 REDUCTION”.

Of these, a matter of priority of “achieving a renewable energy usage ratio” is selected when a user such as the consumer Ca desires to give priority to achieve a usage ratio entered by the user in the above-mentioned field for entering a renewable energy usage ratio. In this case, the intermediary server 5 transfers an ownership of the electricity (asset) that is produced with a relatively large amount of carbon dioxide emissions in order to prioritize “achieving the renewable energy usage rate of 40%”.

In addition, a matter of priority of “achieving the lowest cost” is selected when a user such as the consumer Ca desires to give priority to achieve the lowest cost for the electricity (asset). In this case, the intermediary server 5 transfers an ownership of the electricity (asset) having a low price according to electricity prices (asset prices, item prices) set in advance.

In addition, a matter of priority of “minimizing oxygen dioxide emissions” is selected when a user such as the consumer Ca desires to give priority to minimize oxygen dioxide emitted in producing the electricity (asset). In this case, the intermediary server 5 transfers an ownership of the electricity (asset) produced with the smallest carbon dioxide emissions, based on the carbon dioxide emission amount information. For example, both of “solar power” and “wind power” used for producing the asset such as the electricity do not generate carbon dioxide during the assets is being produced. However, regarding the carbon dioxide emitted in installing or constructing solar panels or wind turbines, “wind power” emits less carbon dioxide than “solar power”. Accordingly, the intermediary server 5 transfers an ownership of the electricity (asset) produced by wind power when there is the ownership having the electricity (asset) produced by wind power. The number of matters of priority for setting a production method may be two or four or more. Alternatively, without the section for selecting a matter of priority for setting a production method, the renewable energy usage ratio may be prioritized by default, for example.

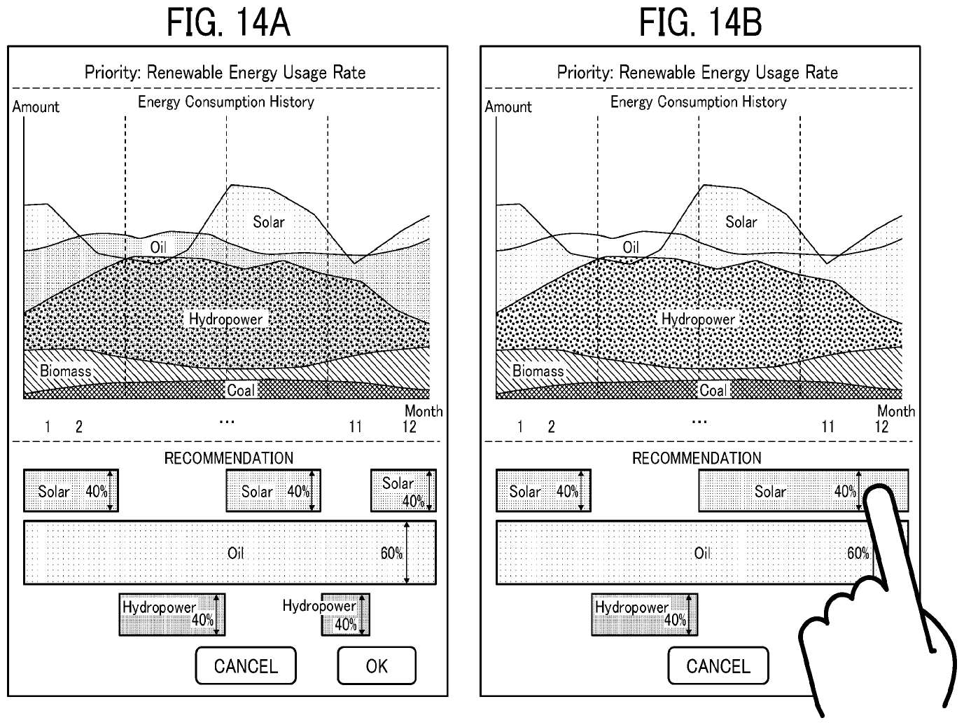

The detail setting button (“DETAILS” button) is a button for displaying a usage plan setting screen for setting details regarding a selected matter of priority, after one of the plurality of matters of priority is selected. FIGS. 14 to 16 are illustrations of example usage plan setting screens each of which corresponds to one of the plurality of matters of priority. A detailed description of the planned usage setting screen is given later.

The usage conditions registration screen further includes, at a lower part of the screen, an “OK” button to be pressed to confirm the usage conditions and the set details, and a “CANCEL” button to be pressed to cancel all the usage conditions and the set details.

Referring back to FIG. 12B, the consumer Ca operates the touch panel of the smartphone 2c to enter any desired numerical value in each input field, further checks a check box of any desired matter of priority. When the consumer Ca presses the “OK” button, the operation input unit 22c receives operations including the inputs entered in the input fields, the selected matter of priority, and pressing of the “OK” button on the usage conditions registration screen illustrated FIG. 12A (S46 in FIG. 11). Namely, by receiving the user operations (user inputs), the operation input unit 22c receives information on the conditions specified by the consumer Ca. In the example of the embodiment, the renewable energy usage ratio is set to 40% by the consumer Ca.

Next, the transmission and reception unit 21c of the smartphone 2c transmits the information on the usage conditions received at S46 to the intermediary server 5 via the communication network 100 (S47). The information on the usage conditions may be referred to as usage condition information. Accordingly, the transmission and reception unit 51 of the intermediary server 5 receives the usage condition information.

Subsequently, at the intermediary server 5, the storing and reading unit 59 reads a record of past electricity usage that indicates the usage in a predetermined period in the past (for example, in the past one year). The record includes information on a total usage amount for each type of production method used by users (S48). Then, the storing and reading unit 59 reads the carbon dioxide emission amount information and the item price information from the storage unit 5000 (S49).

Then, the first determination unit 53 determines recommended details as a recommendation (first energy consumption recommendation) based on the information on the specified conditions for future energy consumption received at step S47, the information on the total usage amount for each type of production method read at S48, and the carbon dioxide emission amount information and the item price information read at S49. (S50). In the example case of FIG. 12B, in which “40”% is entered as a renewable energy usage ratio, and “achieving a renewable energy usage ratio” is selected among the plurality of matters of priority, the first determination unit 53 determines a recommendation (first energy consumption recommendation) including a recommended type of production method, by giving the highest priority to the renewable energy usage ratio of 40%, giving the second priority to the total usage amount for each production method in the past, and giving the third priority to the monthly item price for each type of production method. The determined recommendation is for a predetermined period (for example, a year), the predetermined period is divided into predetermined sub-periods (for example, months). The total usage amount for each production method in the past is taken into account in order to stably provide consumers Ca with the item produced by a specific type of production method. The second priority and the third priority may be replaceable. The user such as the consumer Ca may set the second and subsequent priorities.

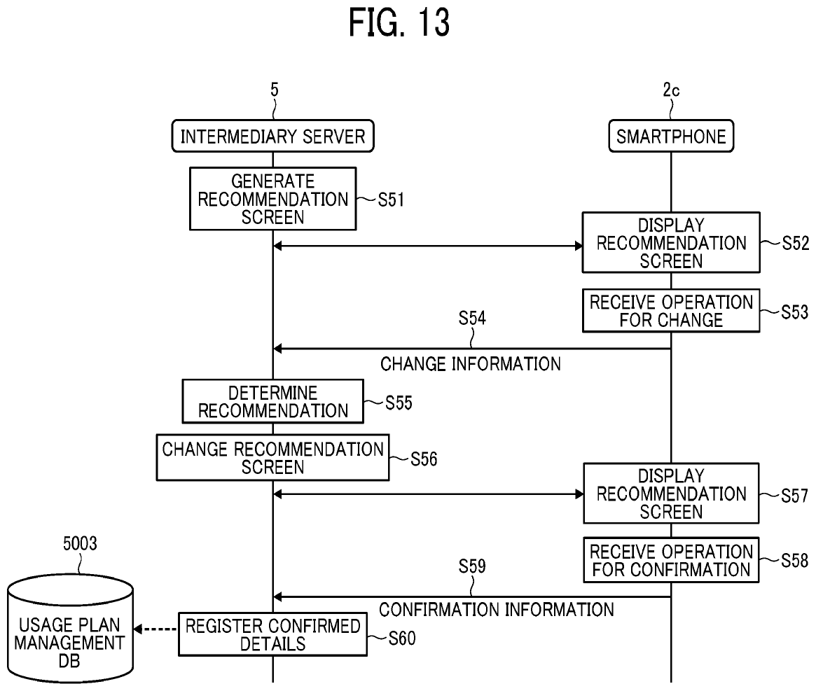

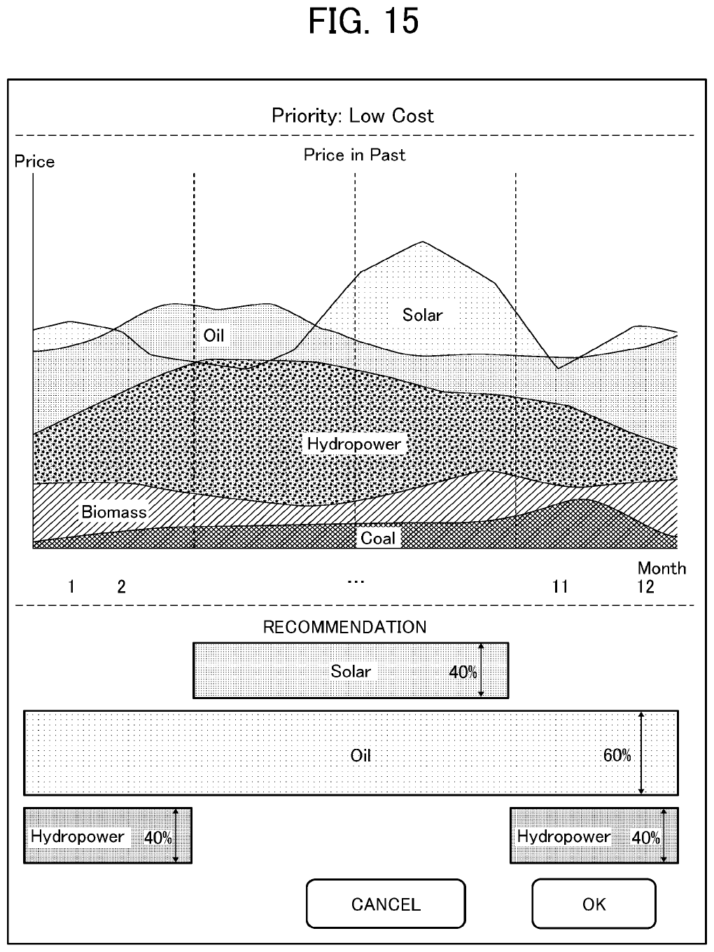

A description is given below of a process for finalizing or confirming a usage plan (plan for future energy consumption) with reference to FIGS. 13 to 16. FIG. 13 is a sequence diagram illustrating processing of registering a usage plan for an item (plan for future energy consumption) according to the embodiment. FIG. 14A is an illustration of an example of a usage plan setting screen, in particular, the usage plan setting screen displaying a recommendation (first energy consumption recommendation) originally provided by giving priority to achieving the renewable energy usage ratio. FIG. 14B is an illustration of a usage plan setting screen displaying another recommendation (second energy consumption recommendation) after the previous recommendation, which is provided by giving priority to achieving the renewable energy usage ratio, is changed, or modified, according to a user operation. FIG. 15 is an illustration of a usage plan setting screen displaying a recommendation that is determined by giving priority to the lowest cost. FIG. 16 is an illustration of a usage plan setting screen displaying a recommendation that is determined by giving priority to the CO2 emissions reduction.

In the following description of the exemplary embodiment, the case where “achieving a renewable energy usage ratio” is selected as the matter of priority in step S46, as illustrated in FIG. 12B, is described as an example.

As illustrated in FIG. 13, the display control unit 54 generates a recommendation screen as illustrated in FIG. 14A based on the recommended details determined in step S50 (S51). Accordingly, the display control unit 24c of the smartphone 2c displays, on the display 218 of the smartphone 2c, the recommendation screen illustrated in FIG. 14A, which is generated by the intermediary server 5, by the web browser function (S52). The recommendation screen may be generated at the smartphone 2c, by using its web browser function, based on the information received from the intermediary server 5. Alternatively, an application (“app”) installed on the smartphone 2c may perform the same functions as the web browser function described throughout this application. The initial screen of the recommendation screen, which is also the usage plan setting screen with a setting of a selected matter of priority, renewable energy usage ratio, displays, in an upper half area of the screen, a graph indicating an “energy consumption history” (record of past usage) and displays, in a lower half area of the screen, a “recommendation” (first energy consumption recommendation) for the usage plan, namely the future energy consumption. More specifically, the graph indicates a total electricity usage amount for each month for each production method (resource) based on the information read in S48. The recommendation indicates the “recommended details”, which are displayed as the “recommendation” on the screen and determined in S50.

The “energy consumption history” corresponds to the last one year and includes records each corresponds to a type of production method. The vertical axis indicates a usage amount, and the horizontal axis indicates a month. In addition, a corresponding energy resource name is displayed for each production method.

The “recommendation”, which is recommended details, indicates a production method and a ratio of the production method for each month. The recommendation is determined by the intermediary server 5 based on the renewable energy usage ratio input in FIG. 12B. In the “recommendation”, each production method is represented by a visual indicator. As an example of the visual indicator, a rectangular area is used in the embodiment. For example, a length in the horizontal direction of the rectangular area indicates a period of use, and a length in the vertical direction of the rectangular area indicates a usage ratio. In the example of FIG. 14A, electricity produced by oil is recommended throughout the year, because supply and price of the electricity produced by oil are stable. In addition, electricity produced by solar light is recommended during a period when an amount of the electricity produced by solar light is high, and electricity produced by hydropower is recommended during another period when the amount of the electricity produced by solar light is low, based on the record of past usage. In addition, since consumer Ca has set the renewable energy usage ratio to 40% and has selected the matter of priority of the renewable energy usage ratio, electricity that is produced with 40% of renewable energy is indicated for every month in the recommendation. In addition, each of the months of the record of past usage and the corresponding one of the months in the recommendation for future usage (future energy consumption) are the same month, but one year off. Namely, the period of use for the visual indicator coincides in a horizontal direction with a same period of use for a previous year in the record of past energy consumption.

The recommendation screen includes an “OK” button and a “CANCEL” button at a lower part of the screen. The “OK” button is pressed when a user confirms and finalizes the displayed details, and the “CANCEL” button is pressed when a user cancel the confirmation or the registration.

When the consumer Ca changes the rectangular area of a certain type of production method, for example, with his or her finger in order to change, or modify, the recommended details to the desired details, the operation input unit 22c receives the change (S53). For example, when the consumer Ca changes a dimension of the rectangular area of a certain type of production method in the horizontal direction, the period of use is changed. In addition, when the consumer Ca changes a dimension of the rectangular area of a certain type of production method in the vertical direction, the usage ratio is changed. In the example of FIG. 14B, a rectangular area of a type of production method that is “solar light” is extended in the horizontal direction to extend the period of use.

The transmission and reception unit 21 of the smartphone 2c transmits change information indicating the change, or the modification, which is the changed dimension, received at S53 to the intermediary server 5 (S54). Accordingly, the transmission and reception unit 51 of the intermediary server 5 receives the change information.

Subsequently, at the intermediary server 5, the first determination unit 53 newly determines a recommendation (second energy consumption recommendation) based on the change information (S55). For example, in a case where the consumer Ca extends a period of use of electricity produced by a first type (for example, solar light), the first determination unit 53 determines a recommendation (second energy consumption recommendation) in which a period of use of electricity produced by a second type (for example, hydropower) becomes shorter than that in the original recommendation (first energy consumption recommendation). Namely, a dimension (length in the horizontal direction, width of the rectangular) of a rectangular area of the second type is shortened to achieve an appropriate balance as a whole. In step S53 described above, in a case where the consumer Ca vertically extends the dimension of the rectangular area of the certain type of production method, which is “sun light” in the example, to increase the usage ratio, the first determination unit 53 determines the recommendation (second energy consumption recommendation) in a manner that a usage ratio of the electricity produced by “oil” in the corresponding period is reduced. Namely, a dimension (length in the vertical direction, height of the rectangular) of the rectangular area of the “oil” is changed to achieve an appropriate balance as a whole based on the modification performed by the consumer Ca.

Then, the display control unit 54 changes the recommendation screen in order to reflect the recommendation (second energy consumption recommendation) determined in step S55 (S56). Accordingly, the display control unit 24c of the smartphone 2c displays, on the display 218 of the smartphone 2c, a recommendation screen, similar to what is illustrated in FIG. 14B, which is changed from the previously-displayed screen by the intermediary server 5 by the web browser function (S57). In the example of the exemplary embodiment, in a recommendation area in the setting screen with a priority setting of the renewable energy usage ratio, the period of use of the electricity (asset) produced by hydropower is shortened by the same length equal to a length corresponding to the extended period of use of the electricity (asset) produced by solar light.

Then, in response to a user operation of pressing the “OK” button performed by the consumer Ca, the operation input unit 22c accepts the confirmation of the recommendation (S58). Subsequently, the transmission and reception unit 21c transmits, to the intermediary server 5, confirmation information indicating that the recommendation has been confirmed. Accordingly, the transmission and reception unit 51 of the intermediary server 5 receives the confirmation information.

At the intermediary server 5, the storage and reading unit 59 stores the recommendation determined at S55 and indicating the determined details in the usage plan management DB 5003 as a usage plan, which is namely a plan for future energy consumption (see FIG. 8A) (S60). There may be a case that a user such as the consumer Ca accepts the original recommendation without changing the recommended details. In such a case, in FIG. 13, the steps from S53 to S57 are not performed, and the process proceeds from S52 directly to S58. Namely, the user confirms the original recommendation (first energy consumption recommendation) at S58, the confirmation is output, or displayed, on the display 218 of the smartphone 2c, as details of future energy consumption, and the intermediary server 5 receives confirmation information indicating the confirmation at S59 and registers the confirmation information indicating the confirmation as the details of future energy consumption, which are originally determined by the intermediary server 5 at S50 in FIG. 11.

In a case in which a matter of priority of “achieving the lowest cost” is selected in step S46 in FIG. 12A, a recommendation screen (setting screen with a priority setting of low cost) as illustrated in FIG. 15 is displayed at S52, which is described above. The initial screen of the setting screen with a priority setting of “low cost”, displays, in an upper area of the screen, a graph indicating a “record of price in past” and displays, in a lower area of the screen, recommended details as a recommendation for the usage plan. More specifically, the graph indicates a price of the asset for each production method on a monthly basis, based on the information read at S49. The recommendation indicates the “recommended details”, which are displayed as the recommendation on the screen and determined at S50.

As for the “price in past”, a price of the asset one year ago is displayed for each type of production method. The vertical axis indicates a price of the asset, and the horizontal axis indicates a month in a year. In addition, each energy resource name corresponding to a production method is displayed.

A display form of the “recommendation” (how the “recommendation” is displayed) is substantially in the same manner as that in the screen illustrated in FIG. 14A, and the description thereof is omitted.

In the case in which a matter of priority of “minimizing oxygen dioxide emissions” is selected on the screen illustrated in FIG. 12A at S46, a recommendation screen (setting screen with a priority setting of “CO2 Reduction”) as illustrated in FIG. 16 is displayed at S52 described above. The initial screen of the setting screen with a priority setting of “CO2 Reduction”, displays, in an upper area of the screen, a graph indicating an amount of “oxygen dioxide emissions” for each type of production method and displays, in a lower area of the screen, recommended details as a recommendation for the usage plan. More specifically, the graph indicates an amount of “oxygen dioxide emissions” for each type of production method based on the information read at the S49. The recommendation indicates the “recommended details”, which are displayed as the recommendation on the screen and determined at S50.

Each displayed amount of “oxygen dioxide emissions” for a corresponding production method is based on the latest information on an amount of oxygen dioxide emissions. In the case of the priority setting of “CO2 Reduction”, the displayed amounts of “oxygen dioxide emissions” do not have relationship with the displayed months of use in the recommendation on the recommendation screen.

A display form of the “recommendation” (how the “recommendation” is displayed) is substantially in the same manner as that in the screen illustrated in FIG. 14A, and the description thereof is omitted. As mentioned above, for example, both of “solar light” and “wind power” used for producing the asset such as the electricity do not generate carbon dioxide during the productions. However, regarding the carbon dioxide emitted in installing or constructing solar panels and wind turbines, “wind power” emits less than “solar light”. Accordingly, the intermediary server 5 determines the recommendation in which using the electricity (asset) produced by the wind power is recommended, when the ownership has the asset produced by wind power.

Note that the data, or one or more records, related to past asset usage (past energy consumption) illustrated in FIGS. 14A, 14B, 15 and 16 maybe data, or one or more records, stored by each energy transaction executed through the blockchain network 90, or may not be data, or one or more records, stored by energy transaction executed through the blockchain network 90.

The processing of registering the usage plan thus ends.

### Processing of Setting the Intermediary Agent as an Owner of the Asset:

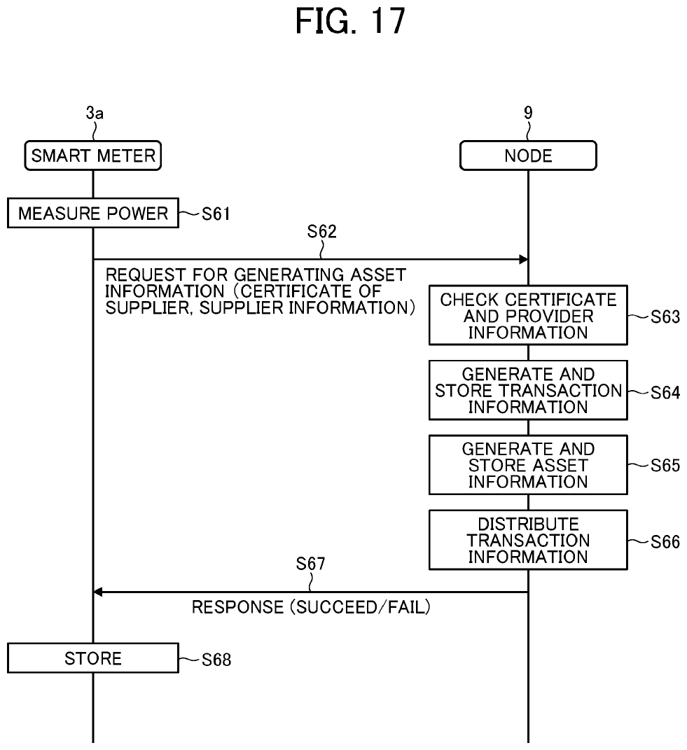

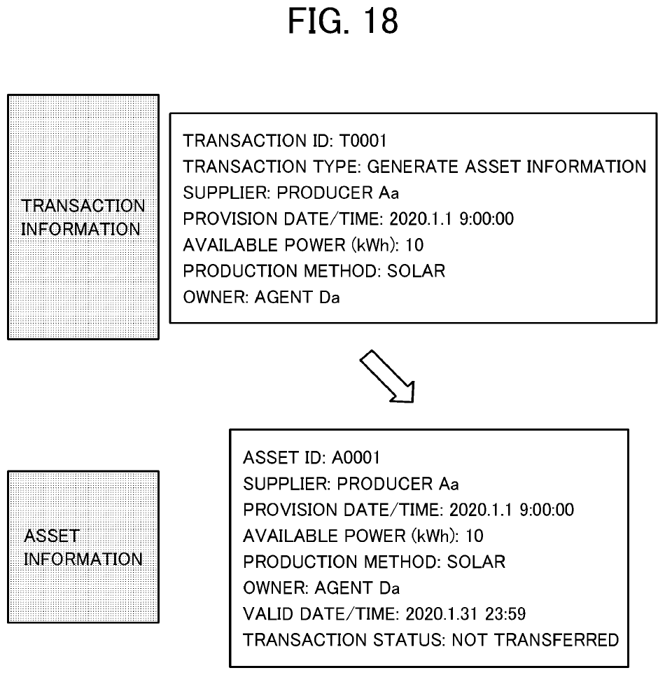

Referring now to FIGS. 17 and 18, processing of setting the intermediary agent as an owner of the asset provided by the supplier is described, according to the embodiment. FIG. 17 is a sequence diagram illustrating processing of setting the intermediary agent as an owner of the asset provided by the supplier, according to the embodiment. FIG. 18 is a conceptual diagram illustrating transaction information and asset information according to the embodiment. The following describes the example case in which the smart meter 3a of the producer Aa requests the node 9a to set the intermediary agent as an owner of the asset.

As illustrated in FIG. 17, the measurement unit 33a measures electricity supplied from the power generator 4a to the power grid 10 (S61). The transmission and reception unit 31a of the smart meter 3a transmits a request for generating asset information to one of the nodes 9 (such as the node 9a) of the blockchain network 90 every predetermined time (for example, every 30 minutes) (S62). This request includes an electronic certificate certifying that the producer Aa is a legitimate registered supplier, and supplier information, so that the smartphone 2a of the producer Aa as the supplier can access the blockchain network 90. The supplier information includes various information on the supplier of the asset, such as the supplier ID or name, the date and time when asset is supplied, an available amount of asset, a production method of asset, and an owner of asset. Accordingly, the transmission and reception unit 91 of the node 9a receives the request for generating asset information (S62). This supplier information is information used for generating the transaction information illustrated in FIG. 18. The contents of the supplier information are determined in advance by a smart contract of the blockchain (contract automation).

Next, the verification unit 93 of the node 9a verifies the certificate and the supplier information received at S62 (S63). The following describes the example case in which the verification result indicates that verification is successful.

Next, the transaction processing unit 96 uses the supplier information received at S62 to generate transaction information as illustrated in FIG. 18 and stores the transaction information in the storage unit 9000 (S64). In this case, the transaction processing unit 96 assigns a transaction ID and sets a transaction type. The transaction information includes a transaction ID, transaction type, and supplier information (supplier name or ID, provision date and time, available amount (power), production method, and owner).

Of these items, the transaction ID is an example of unique identification information for identifying transaction information. The transaction type is information indicating a type of processing to be performed in relation to the asset subjected to transaction. Specifically, the transaction type indicates an instruction in relation to asset information, based on transaction information. In FIG. 18, since the transaction type is generation of asset information, the asset processing unit 97 generates asset information. The supplier ID is identification information identifying a supplier of asset. The provision date and time is information indicating the date and time when the asset is supplied from the supplier. The available amount is information indicating an amount of electricity (electric energy) that the supplier can provide within a certain time period defined by the provision date and time. The type of production method is information indicating a production method of asset illustrated in FIG. 8B. The owner is information indicating an owner of asset, who has ownership of the asset.

Next, the asset processing unit 97 generates the asset information illustrated in FIG. 18 according to the transaction information illustrated in FIG. 18 and stores the asset information in the storage unit 9000 (S65). In this case, the asset processing unit 97 sets, as items of the asset information, the supplier information (supplier ID, date and time of provision, available amount, production method, and owner) in the transaction information, the transaction valid date and time, and the transaction status of the asset information. The transaction valid date and time is set, for example, one month after the date and time of provision. Further, the transaction status is information indicating whether or not the asset information has been transferred (assigned or not) to the user by the intermediary server 5. In FIG. 18, the transaction status of “not transferred” indicates that the asset has not been transferred to (allocated to) the user, that is, the intermediary agent has not yet provided the asset information to the user.

Further, the transmission and reception unit 91 of the node 9a distributes the transaction information generated at S64 as a block to the other nodes 9 (the nodes 9b, 9c, and 9d) of the blockchain network 90 (S66). Each of the other nodes 9 verifies the block, and adds the verified block to a chain of blocks already saved in each node. Each of the other nodes 9 then generates asset information in the same manner as S65 according to the transaction information, and stores the asset information in each storage area. A plurality of items of transaction information may be stored in one block.

Next, the transmission and reception unit 91 of the node 9 transmits a response to the smart meter 3a in response to the request received at S62 (S67). The response indicates whether generation of asset information is successful or fails. Accordingly, the transmission and reception unit 31a of the smart meter 3a receives the response.

Next, at the smart meter 3a, the storing and reading unit 39a stores contents of the response in the storage unit 3000a (S68).

As described above, the asset information indicating that the owner of the asset is the intermediary agent Da is managed on the blockchain network, to complete processing of providing asset information from the supplier to the intermediary agent.

Processing of Providing Asset Information from the Intermediary Agent to the User:

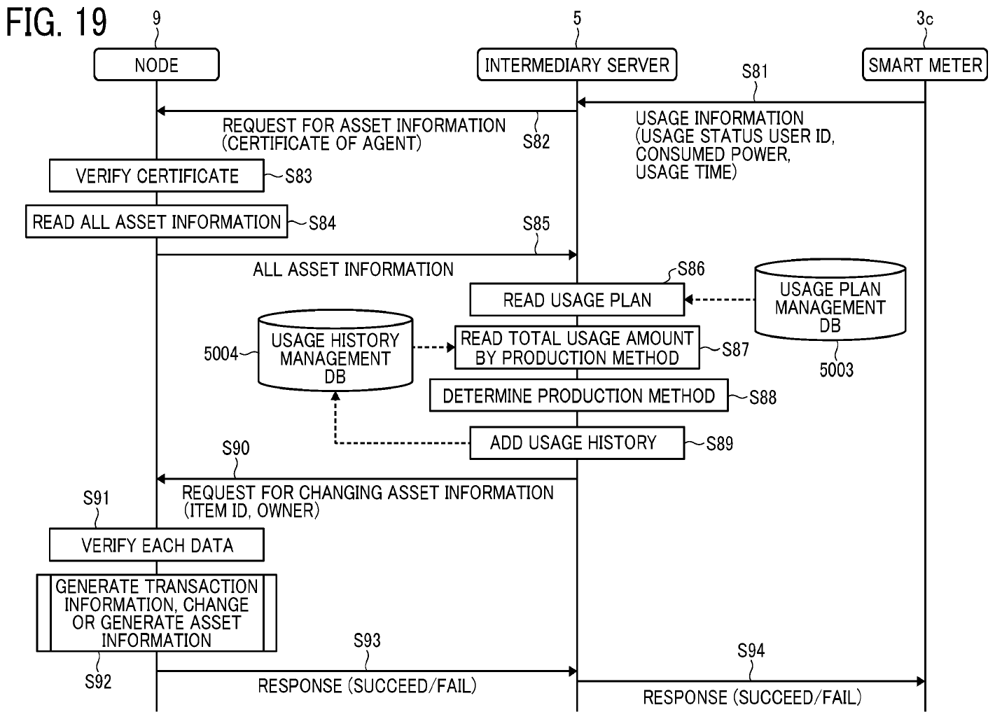

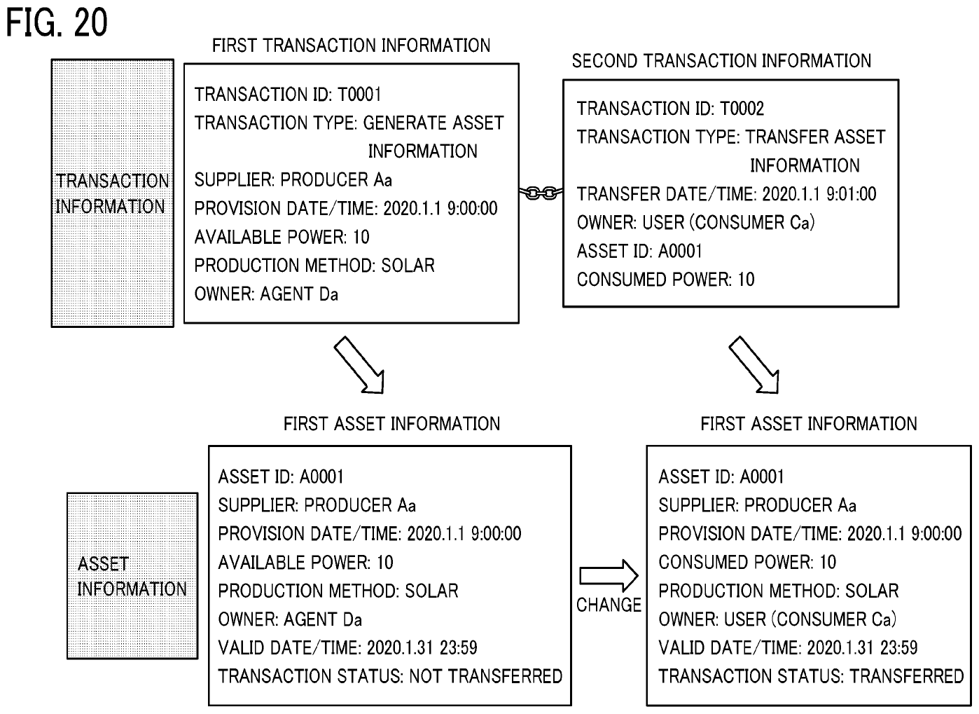

Referring now to FIGS. 19 and 20, processing of setting the user as an owner of the asset is described, according to the embodiment. FIG. 19 is a sequence diagram illustrating processing of setting the user as an owner of the asset, according to the embodiment.

First, the transmission and reception unit 31c of the smart meter 3c of the consumer Ca transmits usage information on usage of electricity, as asset, every predetermined time (for example, every 30 minutes) via the communication network 100 (S81). This usage information includes various information on electricity as asset, such as a usage status of electricity, a user ID for identifying the consumer Ca as the user, the amount of electricity being used, and a time during when electricity is used. The transmission and reception unit 51 of the intermediary server 5 receives the usage information.

The transmission and reception unit 51 transmits a request for all asset information in which the intermediary agent Da of the intermediary server 5 is set as an owner, to the node 9 of the blockchain network 90 (S82). This request includes an electronic certificate certifying that the intermediary agent Da is a legitimate registered intermediary agent, and information indicating the intermediary agent Da as an owner, so that the intermediary server 5 of the intermediary agent Da can access the blockchain network 90. Accordingly, the transmission and reception unit 91 of the node 9 receives the request for all asset information.

Next, the verification unit 93 of the node 9 verifies the certificate received at S82 (S83). The certificate verification is a process of determining whether or not the received certificate is a certificate of the server (in this example, the intermediary server 5) that is registered in advance in the node 9. The following describes the example case in which the verification result indicates that verification is successful.

The storing and reading unit 99 of the node 9 reads out all items of asset information regarding assets indicating that the intermediary agent Da of the intermediary server 5 as the owner (S84). The transmission and reception unit 91 transmits all items of asset information read at S84 to the intermediary server 5 (S85). The transmission and reception unit 51 of the intermediary server 5 receives all the asset information. Accordingly, the intermediary server 5 receives all asset information with ownership that is currently assigned to the intermediary agent Da and can be allocated to the user. Next, the storing and reading unit 59 of the intermediary server 5 searches the usage plan management DB 5003 using the user ID received at S81 as a search key to read out usage plan information corresponding to the user ID (S86). Further, the storing and reading unit 59 searches the usage history management DB 5004 using the user ID received at S81 as a search key to read out total amount of asset having been used by each production method corresponding to the user ID (S87). For example, from the usage history management DB 5004 of FIG. 8B, the storing and reading unit 59 reads 20 (kWh) as total amount of electricity produced from solar light, and 160 (kWh) as total amount of electricity produced from oil, of all electricity consumed by the user.

Next, the first determination unit 53 determines a type of production method of asset, so as to determine particular asset information to be transferred to the consumer Ca as the user, based on the usage plan information read at S86 and total usage amount of asset by each production method that is read at S87 (S88). For example, when the usage plan information indicates two types of production method “solar light” and “oil” are set for the consumer Ca, and the renewable energy usage ratio of 40% is set, since the usage history information indicates that the total usage amount is 20 kWh for solar and 160 kWh for oil (that is, the renewable energy usage ratio is less than 40%), the first determination unit 53 determines the production method to be “solar light” so as to achieve the renewable energy usage ratio of 40%. Accordingly, the first determination unit 53 selects, from among all asset information received at S85, asset information having the production method of solar light, to be transferred to the customer Ca.

The storing and reading unit 59 stores information on usage of asset produced by the production method determined at S88, that is, usage of electricity produced from solar light as indicated by the asset information determined at S88, in the usage history management DB 5004 (S89). Specifically, for example, the storing and reading unit 59 adds, to the usage history management DB 5004 (see FIG. 8B), a record having the usages date and time of “2020.1.1 9:00-9:30”, the usage amount of 10 kWh, the production method of solar light, and the total usage amount of electricity produced from solar light of 30 kWh.

Next, the transmission and reception unit 51 of the intermediary server 5 transmits a request for changing the asset information to the node 9 of the blockchain network 90 (S90). This change request includes an asset ID for identifying the asset information indicating the asset produced from the production method that is determined at S88, from among the asset information received at S85. The change request in step S90 also includes information indicating a new owner. The information indicating the new owner may be the user ID received at S81 or the name of the user as the new owner. When there are a plurality of items of asset information on the asset produced using the specific type of production method determined at S88, the transmission and reception unit 51 determines a request for changing particular asset information, related to the asset having a valid date closet to the current date, from among the plurality of items of asset information.

Next, at the node 9, the verification unit 93 verifies each item of information (asset ID, owner, consumed power) received at S90 (S91). This verification processing is for determining whether or not each item of information has a predetermined content that is written in a predetermined format. The following describes the example case in which the verification result indicates that verification is successful.

Next, the node 9 generates transaction information and changes (or generates) asset information, according to the change request received at S90 (S92).

The processing of S92 is described in detail with reference to FIG. 20. FIG. 20 is a conceptual diagram illustrating a transition of transaction information and asset information in the processing of S92 according to the embodiment. The first transaction information and the first asset information illustrated on the left side of FIG. 20 are the same as the transaction information and the asset information of FIG. 18, respectively. The following describes an example case in which, after the smart meter 3a sets the owner of the asset to the intermediary agent Da (the first asset information is generated based on the first transaction information), the intermediary server 5 changes the owner of the asset to the consumer Ca (the first asset information is changed based on the second transaction information), as the intermediary agent Da intermediates transfer of the asset information (ownership of asset).

At S92, the transaction processing unit 96 generates the third transaction information as illustrated in FIG. 20. The second transaction information includes a unique transaction ID and a transaction type indicating transfer of asset information. The second transaction information additionally includes the transfer date and time when transfer of asset information is intermediated, a new owner of asset as a result of transfer, an asset ID for identifying the asset information that is transferred, and a consumed amount of asset (in this example, electricity) received at S90.

Then, the asset processing unit 97 changes the first asset information to be the second asset information as illustrated in FIG. 20. The asset processing unit 97 changes the “available amount (power)” in the first asset information to the “consumed amount (power)” in the second asset information, and changes the owner from the “intermediary agent Da” in the first asset information to the “consumer Ca” in the second asset information. Furthermore, the asset processing unit 97 changes the transaction status from “not transferred” in the first asset information to “transferred” in the second asset information. The asset information whose transaction status has been changed to “transferred” through this processing will be excluded from a target of transfer in the future. Therefore, the transaction processing unit 96 does not refer to the asset information having the transaction status of “transferred”, as asset information subjected to processing the transaction information having the transaction type of “transfer asset information”. That is, the asset information excluded from the target of transfer is not re-transferred.

Thus, the processing of S92 ends.

Subsequently, returning to FIG. 19, the transmission and reception unit 91 of the node 9 transmits a response to the request received at S90 to the intermediary server 5 (S93). This response indicates that processing performed in response to the request received at S90 succeeded or failed. The transmission and reception unit 51 of the intermediary server 5 receives the response.

Next, the transmission and reception unit 51 of the intermediary server 5 transmits a response to the information received at S81 to the smart meter 3c (S94). Accordingly, the transmission and reception unit 31c of the smart meter 3c receives the response from the intermediary server 5. This response includes contents of response (success or failure) received at S93, and is stored for management or displayed by the smart meter 3c.

### Facilitating Procedure for Obtaining Production Method Certificate:

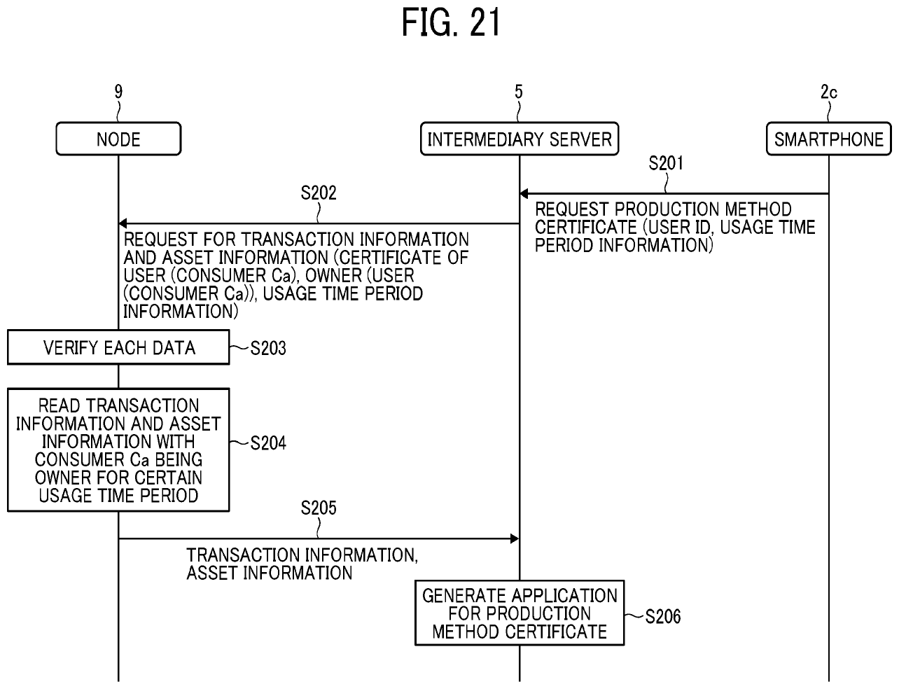

Next, referring to FIG. 21, processing of facilitating procedure for obtaining a production method certificate is described according to the embodiment. FIG. 21 is a sequence diagram illustrating processing of facilitating procedure for obtaining a production method certificate of asset, according to the embodiment. The consumer Ca transmits a request for obtaining a production method certificate from the certification authority E, to the intermediary agent Da. The production method certificate certifies that electricity consumed by the consumer Ca has been produced from renewable energy source, such as a solar light. The following describes this processing in detail.

As illustrated in FIG. 21, according to operation of the consumer Ca on the smartphone 2c, the transmission and reception unit 21c transmits a request for obtaining a production method certificate of asset via the communication network 100 (S201). Accordingly, the transmission and reception unit 51 of the intermediary server 5 receives the request for obtaining a production method certificate. This request includes a user ID for identifying the consumer Ca as the user, and information on a usage time period during when asset is being used. For example, the consumer Ca requests for a production method certificate of asset, for a usage time period from Jan. 1, 2020 to Jan. 31, 2020.

Next, the transmission and reception unit 51 of the intermediary server 5 transmits a request for transaction information and asset information to the node 9 of the blockchain network 90 (S202). This request includes information on a certificate of the user (here, consumer Ca) that the intermediary server 5 previously acquires from the smartphone 2c, information indicating the user as the owner (here, consumer Ca), and a usage time period. Accordingly, the transmission and reception unit 91 of the node 9 receives the request. The certificate of the intermediary server 5 has the same contents as that of the certificate transmitted from the intermediary server 5 to the node 9 at S82. Further, the usage time period information has the same contents as that of the usage time period information received at S201.

Next, the verification unit 93 of the node 9 verifies the certificate received at S202 (S203). The certificate verification is a process of determining whether or not the received certificate is a certificate of the server (in this example, the intermediary server 5) that is registered in advance in the node 9. The following describes the example case in which the verification result indicates that verification is successful.

Next, the storing and reading unit 99 reads out the transaction information and the asset information in which the consumer Ca is set as the owner, within a predetermined usage time period indicated by the usage time period information received at S202 (S204). In this case, the storing and reading unit 99 reads out particular transaction information having the usage date and time that falls within the predetermined usage time period and the new owner of the consumer Ca. Further, the storing and reading unit 99 reads the asset information having the asset ID, which is indicated by the particular transaction information that is read.

Then, the transmission and reception unit 91 of the node 9 transmits the requested transaction information and asset information to the intermediary server 5 (S205). Accordingly, the transmission and reception unit 51 of the intermediary server 5 receives the transaction information and the asset information.

Next, at the intermediary server 5, the creation unit 58 creates an application form to be submitted by the intermediary agent to the certification authority E, based on the transaction information and the asset information received at S205 (S206). This application form is used to apply for a production method certificate to prove the type of production method for the asset.

Subsequently, as illustrated in FIG. 1, the intermediary agent Da sends the application form created at S206 to the certification authority E by mail or the like (S1). Then, the certification authority E creates a production method certificate of asset, which certifies that 40% of electricity consumed by the consumer Ca has been produced from renewable energy source such as solar light, and sends the production method certificate by mail or the like to the intermediary agent (S2). Then, the intermediary agent Da sends the production method certificate to the consumer Ca by mail or the like (S3). If necessary, the certification authority E may acquire transaction information and asset information from the blockchain network 90 and confirm the contents before issuing the production method certificate.

The processing of facilitating procedure for obtaining the production method certificate by the intermediary agent Da then ends. The consumer Ca is able to use the production method certificate to enhance public image of the company or apply the government for a subsidy based on use of renewable energy.

However, as mentioned above, there are multiple types of energy resources used to produce an item, or asset. In addition, there is a plurality of types of production methods for producing the item by using one of the multiple types of energy resources. Due to such complexity, the users have the difficulty to select which types of production methods to use.

According to one or more embodiments of the present disclosure, the difficulty that the users of the item (asset) have when selecting which types of production methods to use is reduced.

According to the embodiment described above, the intermediary server 5 presents the recommended details (recommendation) as illustrated in each of FIGS. 14A to 16. This allows a user such as the consumer Ca to easily select which type of production method to be used for producing the asset such as the electricity, without spending a lot of time to determine a usage plan or being distressed for determining the usage plan. In addition, in a point of view of the intermediary agent, the recommended details bring an advantage to successfully acquire a customer, because the customer uses the recommended details and has less difficulty to select or accept the details for the usage plan.

For some assets such as electricity, even though qualities of assets provided to the user are kept constant, it has been difficult to prove how the asset is produced. In view of this, according to the above-described embodiments, the node 9 of the blockchain network 90 generates asset information indicating a type of production method of asset and ownership of asset, and transaction information from which such asset information is generated. Through managing these asset information and transaction information, a production method of asset can be verified, and a production method certificate can be issued based on this verification.

Moreover, in order to encourage stable consumption of electricity, it is necessary to adjust the consumed electricity and the produced electricity in real time to make them equal. Since the blockchain is a decentralized ledger system, it takes a certain amount of time to confirm consistency of each ledger information via the network. Therefore, it is not suitable to apply the blockchain technology to track use of such asset, which requires responsiveness in real time, as in the case of electricity use. In view of this, in the exemplary embodiment, the intermediary server 5 is configured to transmit a request for changing the ownership of the asset information on the blockchain network 90 from the original owner to the user (consumer Ca), not at a time when the consumer Ca starts using the asset (electricity), but after the consumer Ca has consumed the asset (electricity) (S89). Through this processing, which allows processing like deferred payment, the blockchain technology can be applied to exchange of asset, or transfer of ownership of asset, requiring real-time processing. While the above-described embodiment uses electricity as such asset requiring real-time processing, any other type of energy, is applicable as secondary energy such as hydrogen. Moreover, since the intermediary server 5 changes the asset information managed by the blockchain network 90 on behalf of the supplier (producer Aa, etc.) and the user (consumer Ca, etc.), the supplier (producer Aa, etc.) and the user (consumers Ca, etc.) can exchange electricity, without any need to consider whether the asset information has been changed.

Further, the intermediary server 5 is able to transfer the ownership of particular asset produced with a specific production method, such that exchange of electricity produced from renewable energy source such as solar light can be effectively tracked.

In any one of the above-described embodiments, the asset information includes information on the owner of the asset, however, the asset information may not include such information on the owner. For example, when the user is consuming electricity produced by the user, such that the user is the producer of the asset, there is no need to transfer the asset to another entity (another person or another company), as long as a type of production method can be verified.

Further, in any one of the above-described embodiments, electricity is used as an example of asset, which is an item having value. Examples of asset include any other tangible asset that physically exists, and any other non-tangible asset that does not physically exist.

Examples of tangible asset include, but are not limited to, foods such as grains, vegetables, fruits, meats, marine products, or processed foods. For example, by tracking asset information including additional information on how the food is produced, determination of whether the food confirms some standards (for example, organic labeling standards) may be made easier. When the assets are grains, vegetables and fruits, the asset information includes information indicating whether or not pesticides have been used, or information indicating a producer or a place of production. When the asset is meat, the asset information includes information indicating whether or not the animal is bred using a genetically modified crop, or information indicating a producer or a place of production. When the asset is a marine product such as fish or shellfish, the asset information includes information indicating a natural product or aquaculture, or information indicating a producer (fisherman) or a production area (fishing area). When the asset is a processed product, the asset information includes information indicating an allergen, information indicating whether or not the product has been processed using a genetically modified crop, or information indicating a location of a processor or a processing plant.

Examples of non-tangible asset include, but are not limited to, real estate such as land and buildings, and movable property such as goods or quantity of goods. When the asset is real estate, the asset information includes information such as ownership of the asset. When the asset is movable property, the asset information includes information such as ownership of the asset.

On the other hand, examples of non-tangible asset include, but are not limited to, tokens (virtual currency) or quantity of tokens, carbon dioxide emission credits, intellectual property rights, and contracts. When the asset is a token, the asset information includes information on such as ownership of the asset. When the asset is a carbon dioxide emission credit, the asset information includes information on such as ownership of the asset. When the asset is a right such as an intellectual property right, the asset information includes information on such as the owner of the right, the transferee of the right, and the licensee. When the asset is a contract, the asset information includes information on such as contract conditions and contract performance. In addition or in alternative to contracts, treaties, agreements, promises, and memorandums (memos) may be treated as asset.

Further, other types of asset that can be managed in a substantially similar manner as the example case of electricity, to allow postpaid processing, include gas (other form of energy), water, and communication. In the case of gas, water, or communication, the asset information includes information such as ownership of the asset.

Each of the above-described hardware components, like CPU 201, 301, 501, and 901, may be a single device or a plurality of devices.

Each of the functions of the described embodiments may be implemented by one or more processing circuits or circuitry. Processing circuitry includes a programmed processor, as a processor includes circuitry. A processing circuit also includes devices such as an application specific integrated circuit (ASIC), digital signal processor (DSP), field programmable gate array (FPGA), System on Chip (SOC), and graphical processing unit (GPU), and conventional circuit components arranged to perform the recited functions.

Further, the power generator 4a (4b) may be additionally provided with a smart meter 3a (3b), or has a function of the smart meter 3a (3b). Alternatively or additionally, the electric device 8 maybe provided with the smart meter 3c, or has a function of the smart meter 3c.

Further, any of the above-described programs may be stored in a recording medium such as a DVD for distribution.

Further, another server or the like may relay data between the smartphone 2 (or smart meter 3), the intermediary server 5, and each node 9. The above-described embodiments are illustrative and do not limit the present invention.

Thus, numerous additional modifications and variations are possible in light of the above teachings. For example, elements and/or features of different illustrative embodiments may be combined with each other and/or substituted for each other within the scope of the present invention.

Any one of the above-described operations may be performed in various other ways, for example, in an order different from the one described above.

What is claimed:

1. A communication terminal, comprising:
circuitry configured to
receive an input of information including information on a period of use for electricity, a planned electricity consumption, and a renewable energy usage ratio;
transmit, to a registration server communicably connected to the communication terminal via a communication network, the information received, the registration server registering details of an electricity transaction to be executed; and
display, on a display, one or more recommended types of production methods for the electricity, the one or more recommended types of production methods for the electricity being determined by the registration server based on the information on the period of use for the electricity, the planned electricity consumption, and the renewable energy usage ratio, wherein
the information includes a matter of priority of production method, a total amount of electricity transactions performed in a predetermined period for each of all production methods, carbon dioxide emission amount information, and electricity price information.

2. A displaying method, comprising:
receiving an input of information including information on a period of use for electricity, a planned electricity consumption, and a renewable energy usage ratio;
transmitting, to a registration server communicably connected to the communication terminal via a communication network, the information received, the registration server registering details of an electricity transaction to be executed; and
displaying, on a display, one or more recommended types of production methods for the electricity, the one or more recommended types of production methods for the electricity being determined by the registration server based on the information on the period of use for the electricity, the planned electricity consumption, and the renewable energy usage ratio, wherein
the information includes a matter of priority of production method, a total amount of electricity transactions performed in a predetermined period for each of all production methods, carbon dioxide emission amount information, and electricity price information.

3. The communication terminal of claim 1, wherein each of the one or more recommended types of production methods for the electricity is a type of production method indicating a renewable energy and fossil fuel.

4. The communication terminal of claim 1, wherein the circuitry is further configured to display, on the display, a period of use for each of the one or more recommended types of production methods.

5. The communication terminal of claim 4, wherein the period of use is indicated by a dimension of a visual indicator.

6. The communication terminal of claim 5, wherein the circuitry is further configured to:
receive a user operation of changing a dimension of a first visual indicator indicating a period of use for an asset produced by a first type of production method, the first type of production method being included in the one or more recommended types of production methods;
transmit, to the registration server, information on the dimension that is changed; and
display, on the display, another dimension of a second visual indicator indicating another period of use for an asset produced by a second type of production method, the second type of production method being included in the one or more recommended types of production methods, the another dimension of the second visual indicator being determined by the registration server according to the change in the dimension of the first visual indicator.

7. The communication terminal of claim 6, wherein the circuitry is further configured to display, on the display, one or more usage ratios corresponding to the one or more recommended types of production methods for the asset, respectively.

8. The communication terminal of claim 7, wherein a usage ratio of the asset produced by the first type of production method is indicated by a different dimension of the first visual indicator, the different dimension being a direction that is different from that of the dimension of the first visual indicator.

9. The communication terminal of claim 8, wherein the circuitry is further configured to:
receive a user operation of changing the different dimension of the first visual indicator;
transmit, to the registration server, information on the different dimension that is changed; and
display, on the display, another different dimension of the second visual indicator indicating another usage ratio of the asset produced by the second type of production method, the another different dimension of the second visual indicator being determined by the registration server according to the change in the different dimension of the first visual indicator.

10. The communication terminal of claim 6, wherein the circuitry is further configured to:
receive one or more user inputs specifying conditions to be used by the registration server to determine the one or more recommended types of production methods for the asset; and
transmit, to the registration server, information on the conditions.

11. The communication terminal of claim 10, wherein the conditions include additional usage ratio of a renewable energy used to produce the asset.

12. The communication terminal of claim 10, wherein the conditions include a planned consumption of the asset in a period of time in the transaction.

13. The communication terminal of claim 10, wherein the conditions include a matter of priority in determining the one or more recommended types of production methods.

14. The communication terminal of claim 10, wherein the matter of priority includes one of achieving a usage ratio of a renewable source, achieving a lowest price, and achieving a highest reduction of carbon dioxide emissions.

15. A transaction system, comprising:
the communication terminal according to claim 1; and
the registration server.

16. A transaction system, comprising:
a registration server; and
a communication terminal communicably connected to the registration server via a communication network, the communication terminal including circuitry configured to
receive an input of information including information on a period of use for electricity, a planned electricity consumption, and a renewable energy usage ratio;
transmit, to the registration server via the communication network, the information received, the registration server registering details of an electricity transaction to be executed; and
display, on a display, one or more recommended types of production methods for the electricity, the one or more recommended types of production methods for the electricity being determined by the registration server based on the information on the period of use for the electricity, the planned electricity consumption, and the renewable energy usage ratio, wherein
the information includes a matter of priority of production method, a total amount of electricity transactions performed in a predetermined period for each of all production methods, carbon dioxide emission amount information, and electricity price information.
